(19) United States
(12) Patent Application Publication
(10) Pub. No.: US 2011/0147889 A1
(43) Pub. Date: Jun. 23, 2011

(54) SEMICONDUCTOR DEVICE AND METHOD OF MANUFACTURING SEMICONDUCTOR DEVICE

(75) Inventor: Keiichi TSUCHIYA, Tokyo (JP)

(73) Assignee: ELPIDA MEMORY, INC., Tokyo (JP)

(21) Appl. No.: 12/965,380

(22) Filed: Dec. 10, 2010

(30) Foreign Application Priority Data
Dec. 18, 2009 (JP) 2009-287803

(51) Int. Cl. H01L 29/94

(52) U.S. Cl. 257/532; 257/E29.345

(57) ABSTRACT

A semiconductor device includes an insulating film over a silicon substrate, the insulating film having an opening and a contact plug in the opening, the contact plug having a first top that is lower than an upper face of the insulating film.

### BACKGROUND OF THE INVENTION

1. Field of the Invention

The present invention relates to a semiconductor device and a method of manufacturing the semiconductor device.

Priority is claimed on Japanese Patent Application No. 2009-287803, Dec. 18, 2009, the content of which is incorporated herein by reference.

2. Description of Related Art

In transistors with a planar structure in which a substrate surface is used as a channel in the related art, the miniaturization of semiconductor devices has led to difficulty in suppressing a short channel effect, and desired transistor characteristics cannot be obtained.

Japanese Unexamined Patent Application, First Publications, Nos. JP-A-2006-339476 and JP-A-2007-081095 disclose using groove gate transistors to suppress the short channel effect.

In the groove gate transistors described in Japanese Unexamined Patent Application, First Publication, No. JP-A-2006-339476 and JP-A-2007-081095, surfaces of grooves formed in a semiconductor substrate are used as channels. Increase in the depth dimension of the groove can suppress the short channel effect, even the horizontal dimensions of the groove are decreased.

### SUMMARY

In one embodiment, a semiconductor device may include, but is not limited to, an insulating film over a silicon substrate, the insulating film having an opening, and a contact plug in the opening, the contact plug having a first top that is lower than an upper face of the insulating film.

In another embodiment, a semiconductor device may include, but is not limited to, a contact plug including a first layer and a second layer. The first layer is over the second layer. The first layer performs as a first part of the contact plug and as a contact pad. The second layer performs as a second part of the contact plug.

In still another embodiment, a semiconductor device may include, but is not limited to, a contact plug over a silicon substrate, a first insulating film over the silicon substrate, and a contact pad. A first top of the contact plug is lower than a second top of the first insulating film. A bottom of the contact pad is lower than the second top of the first insulating film.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a fragmentary plan view illustrating a semiconductor device in accordance with one embodiment of the present invention;

FIG. 2A is a fragmentary cross sectional elevation view, taken along an A-A′ line of FIG. 1, illustrating a memory cell in the semiconductor device of FIG. 1;

FIG. 2B is a fragmentary cross sectional elevation view, taken along a B-B′ line of FIG. 1, illustrating a memory cell in the semiconductor device of FIG. 1;

FIG. 2C is a fragmentary cross sectional elevation view in a peripheral circuit area, illustrating a memory cell in the semiconductor device of FIG. 1;

FIG. 3A is a fragmentary cross sectional elevation view, taken along an A-A′ line of FIG. 1, illustrating a memory cell in a step involved in a method of forming the semiconductor device of FIGS. 1, 2A and 2B;

FIG. 3B is a fragmentary cross sectional elevation view, taken along a B-B′ line of FIG. 1, illustrating a memory cell in a step involved in a method of forming the semiconductor device of FIGS. 1, 2A and 2B;

FIG. 4A is a fragmentary cross sectional elevation view, taken along an A-A′ line of FIG. 1, illustrating a memory cell in a step, subsequent to the step of FIGS. 3A and 3B, involved in the method of forming the semiconductor device of FIGS. 1, 2A and 2B;

FIG. 4B is a fragmentary cross sectional elevation view, taken along a B-B′ line of FIG. 1, illustrating a memory cell in a step, subsequent to the step of FIGS. 3A and 3B, involved in the method of forming the semiconductor device of FIGS. 1, 2A and 2B;

FIG. 5A is a fragmentary cross sectional elevation view, taken along an A-A′ line of FIG. 1, illustrating a memory cell in a step, subsequent to the step of FIGS. 4A and 4B, involved in the method of forming the semiconductor device of FIGS. 1, 2A and 2B;

FIG. 5B is a fragmentary cross sectional elevation view, taken along a B-B′ line of FIG. 1, illustrating a memory cell in a step, subsequent to the step of FIGS. 4A and 4B, involved in the method of forming the semiconductor device of FIGS. 1, 2A and 2B;

FIG. 6A is a fragmentary cross sectional elevation view, taken along an A-A′ line of FIG. 1, illustrating a memory cell in a step, subsequent to the step of FIGS. 5A and 5B, involved in the method of forming the semiconductor device of FIGS. 1, 2A and 2B;

FIG. 6B is a fragmentary cross sectional elevation view, taken along a B-B′ line of FIG. 1, illustrating a memory cell in a step, subsequent to the step of FIGS. 5A and 5B, involved in the method of forming the semiconductor device of FIGS. 1, 2A and 2B;

FIG. 7A is a fragmentary cross sectional elevation view, taken along an A-A′ line of FIG. 1, illustrating a memory cell in a step, subsequent to the step of FIGS. 6A and 6B, involved in the method of forming the semiconductor device of FIGS. 1, 2A and 2B;

FIG. 7B is a fragmentary cross sectional elevation view, taken along a B-B′ line of FIG. 1, illustrating a memory cell in a step, subsequent to the step of FIGS. 6A and 6B, involved in the method of forming the semiconductor device of FIGS. 1, 2A and 2B;

FIG. 8A is a fragmentary cross sectional elevation view, taken along an A-A′ line of FIG. 1, illustrating a memory cell in a step, subsequent to the step of FIGS. 7A and 7B, involved in the method of forming the semiconductor device of FIGS. 1, 2A and 2B;

FIG. 8B is a fragmentary cross sectional elevation view, taken along a B-B′ line of FIG. 1, illustrating a memory cell in a step, subsequent to the step of FIGS. 7A and 7B, involved in the method of forming the semiconductor device of FIGS. 1, 2A and 2B;

FIG. 9A is a fragmentary cross sectional elevation view, taken along an A-A′ line of FIG. 1, illustrating a memory cell in a step, subsequent to the step of FIGS. 8A and 8B, involved in the method of forming the semiconductor device of FIGS. 1, 2A and 2B;

FIG. 9B is a fragmentary cross sectional elevation view, taken along a B-B′ line of FIG. 1, illustrating a memory cell in a step, subsequent to the step of FIGS. 8A and 8B, involved in the method of forming the semiconductor device of FIGS. 1, 2A and 2B;

FIG. 10A is a fragmentary cross sectional elevation view, taken along an A-A′ line of FIG. 1, illustrating a memory cell in a step, subsequent to the step of FIGS. 9A and 9B, involved in the method of forming the semiconductor device of FIGS. 1, 2A and 2B;

FIG. 10B is a fragmentary cross sectional elevation view, taken along a B-B′ line of FIG. 1, illustrating a memory cell in a step, subsequent to the step of FIGS. 9A and 9B, involved in the method of forming the semiconductor device of FIGS. 1, 2A and 2B;

FIG. 11A is a fragmentary cross sectional elevation view, taken along an A-A′ line of FIG. 1, illustrating a memory cell in a step, subsequent to the step of FIGS. 10A and 10B, involved in the method of forming the semiconductor device of FIGS. 1, 2A and 2B;

FIG. 11B is a fragmentary cross sectional elevation view, taken along a B-B′ line of FIG. 1, illustrating a memory cell in a step, subsequent to the step of FIGS. 10A and 10B, involved in the method of forming the semiconductor device of FIGS. 1, 2A and 2B;

FIG. 12A is a fragmentary cross sectional elevation view, taken along an A-A′ line of FIG. 1, illustrating a memory cell in a step, subsequent to the step of FIGS. 11A and 11B, involved in the method of forming the semiconductor device of FIGS. 1, 2A and 2B;

FIG. 12B is a fragmentary cross sectional elevation view, taken along a B-B′ line of FIG. 1, illustrating a memory cell in a step, subsequent to the step of FIGS. 11A and 11B, involved in the method of forming the semiconductor device of FIGS. 1, 2A and 2B;

FIG. 13A is a fragmentary cross sectional elevation view, taken along an A-A′ line of FIG. 1, illustrating a memory cell in a step, subsequent to the step of FIGS. 12A, 12B, and 12C, involved in the method of forming the semiconductor device of FIGS. 1, 2A and 2B;

FIG. 13B is a fragmentary cross sectional elevation view, taken along a B-B′ line of FIG. 1, illustrating a memory cell in a step, subsequent to the step of FIGS. 12A and 12B, involved in the method of forming the semiconductor device of FIGS. 1, 2A and 2B;

FIG. 14A is a fragmentary cross sectional elevation view, taken along an A-A′ line of FIG. 1, illustrating a memory cell in a step, subsequent to the step of FIGS. 13A, 13B, and 13C, involved in the method of forming the semiconductor device of FIGS. 1, 2A and 2B;

FIG. 14B is a fragmentary cross sectional elevation view, taken along a B-B′ line of FIG. 1, illustrating a memory cell in a step, subsequent to the step of FIGS. 13A, 13B, and 13C involved in the method of forming the semiconductor device of FIGS. 1, 2A and 2B;

FIG. 15A is a fragmentary cross sectional elevation view, taken along an A-A′ line of FIG. 1, illustrating a memory cell in a step, subsequent to the step of FIGS. 14A, 14B, and 14C involved in the method of forming the semiconductor device of FIGS. 1, 2A and 2B;

FIG. 15B is a fragmentary cross sectional elevation view, taken along a B-B′ line of FIG. 1, illustrating a memory cell in a step, subsequent to the step of FIGS. 14A, 14B, and 14C involved in the method of forming the semiconductor device of FIGS. 1, 2A and 2B;

FIG. 16A is a fragmentary cross sectional elevation view, taken along an A-A′ line of FIG. 1, illustrating a memory cell in a step, subsequent to the step of FIGS. 15A, 15B, and 15C involved in the method of forming the semiconductor device of FIGS. 1, 2A and 2B;

FIG. 16B is a fragmentary cross sectional elevation view, taken along a B-B′ line of FIG. 1, illustrating a memory cell in a step, subsequent to the step of FIGS. 15A, 15B, and 15C involved in the method of forming the semiconductor device of FIGS. 1, 2A and 2B;

FIG. 17A is a fragmentary cross sectional elevation view, taken along an A-A′ line of FIG. 1, illustrating a memory cell in a step, subsequent to the step of FIGS. 16A and 16B, involved in the method of forming the semiconductor device of FIGS. 1, 2A and 2B;

FIG. 17B is a fragmentary cross sectional elevation view, taken along a B-B′ line of FIG. 1, illustrating a memory cell in a step, subsequent to the step of FIGS. 16A and 16B, involved in the method of forming the semiconductor device of FIGS. 1, 2A and 2B;

FIG. 18A is a fragmentary cross sectional elevation view, taken along an A-A′ line of FIG. 1, illustrating a memory cell in a step, subsequent to the step of FIGS. 17A and 17B, involved in the method of forming the semiconductor device of FIGS. 1, 2A and 2B;

FIG. 18B is a fragmentary cross sectional elevation view, taken along a B-B′ line of FIG. 1, illustrating a memory cell in a step, subsequent to the step of FIGS. 17A and 17B, involved in the method of forming the semiconductor device of FIGS. 1, 2A and 2B;

FIG. 19A is a fragmentary cross sectional elevation view, taken along an A-A′ line of FIG. 1, illustrating a memory cell in a step, subsequent to the step of FIGS. 18A and 18B, involved in the method of forming the semiconductor device of FIGS. 1, 2A and 2B;

FIG. 19B is a fragmentary cross sectional elevation view, taken along a B-B′ line of FIG. 1, illustrating a memory cell in a step, subsequent to the step of FIGS. 18A and 18B, involved in the method of forming the semiconductor device of FIGS. 1, 2A and 2B;

FIG. 20A is a fragmentary cross sectional elevation view, taken along an A-A′ line of FIG. 1, illustrating a memory cell in a step, subsequent to the step of FIGS. 19A and 19B, involved in the method of forming the semiconductor device of FIGS. 1, 2A and 2B;

FIG. 20B is a fragmentary cross sectional elevation view, taken along a B-B′ line of FIG. 1, illustrating a memory cell in a step, subsequent to the step of FIGS. 19A and 19B, involved in the method of forming the semiconductor device of FIGS. 1, 2A and 2B;

FIG. 20C is a fragmentary cross sectional elevation view in the peripheral circuit area, illustrating a memory cell in a step, subsequent to the step of FIGS. 19A and 19B, involved in the method of forming the semiconductor device of FIGS. 1, 2A and 2B;

FIG. 21A is a fragmentary cross sectional elevation view, taken along an A-A′ line of FIG. 1, illustrating a memory cell in a step, subsequent to the step of FIGS. 20A to 20C, involved in the method of forming the semiconductor device of FIGS. 1, 2A and 2B;

FIG. 21B is a fragmentary cross sectional elevation view, taken along a B-B′ line of FIG. 1, illustrating a memory cell in a step, subsequent to the step of FIGS. 20A to 20C, involved in the method of forming the semiconductor device of FIGS. 1, 2A and 2B;

FIG. 21C is a fragmentary cross sectional elevation view in a peripheral circuit area, illustrating a memory cell in a step, subsequent to the step of FIGS. 20A to 20C, involved in the method of forming the semiconductor device of FIGS. 1, 2A and 2B;

FIG. 22A is a fragmentary cross sectional elevation view, taken along an A-A′ line of FIG. 1, illustrating a memory cell in a step, subsequent to the step of FIGS. 21A to 21C, involved in the method of forming the semiconductor device of FIGS. 1, 2A and 2B;

FIG. 22B is a fragmentary cross sectional elevation view, taken along a B-B′ line of FIG. 1, illustrating a memory cell in a step, subsequent to the step of FIGS. 21A to 21C, involved in the method of forming the semiconductor device of FIGS. 1, 2A and 2B;

FIG. 22C is a fragmentary cross sectional elevation view in the peripheral circuit area, illustrating a memory cell in a step, subsequent to the step of FIGS. 21A to 21C, involved in the method of forming the semiconductor device of FIGS. 1, 2A and 2B;

FIG. 23A is a fragmentary cross sectional elevation view, taken along an A-A′ line of FIG. 1, illustrating a memory cell in a step, subsequent to the step of FIGS. 22A to 22C, involved in the method of forming the semiconductor device of FIGS. 1, 2A and 2B;

FIG. 23B is a fragmentary cross sectional elevation view, taken along a B-B′ line of FIG. 1, illustrating a memory cell in a step, subsequent to the step of FIGS. 22A to 22C, involved in the method of forming the semiconductor device of FIGS. 1, 2A and 2B;

FIG. 23C is a fragmentary cross sectional elevation view in the peripheral circuit area, illustrating a memory cell in a step, subsequent to the step of FIGS. 22A to 22C, involved in the method of forming the semiconductor device of FIGS. 1, 2A and 2B;

FIG. 24A is a fragmentary cross sectional elevation view, taken along an A-A′ line of FIG. 1, illustrating a memory cell in a step, subsequent to the step of FIGS. 23A to 23C, involved in the method of forming the semiconductor device of FIGS. 1, 2A and 2B;

FIG. 24B is a fragmentary cross sectional elevation view, taken along a B-B′ line of FIG. 1, illustrating a memory cell in a step, subsequent to the step of FIGS. 23A to 23C, involved in the method of forming the semiconductor device of FIGS. 1, 2A and 2B;

FIG. 24C is a fragmentary cross sectional elevation view in the peripheral circuit area, illustrating a memory cell in a step, subsequent to the step of FIGS. 23A to 23C, involved in the method of forming the semiconductor device of FIGS. 1, 2A and 2B;

FIG. 25A is a fragmentary cross sectional elevation view, taken along an A-A′ line of FIG. 1, illustrating a memory cell in a step, subsequent to the step of FIGS. 24A to 24C, involved in the method of forming the semiconductor device of FIGS. 1, 2A and 2B;

FIG. 25B is a fragmentary cross sectional elevation view, taken along a B-B′ line of FIG. 1, illustrating a memory cell in a step, subsequent to the step of FIGS. 24A to 24C, involved in the method of forming the semiconductor device of FIGS. 1, 2A and 2B;

FIG. 25C is a fragmentary cross sectional elevation view in the peripheral circuit area, illustrating a memory cell in a step, subsequent to the step of FIGS. 24A to 24C, involved in the method of forming the semiconductor device of FIGS. 1, 2A and 2B;

FIG. 26A is a fragmentary cross sectional elevation view, taken along an A-A′ line of FIG. 1, illustrating a memory cell in a step, subsequent to the step of FIGS. 25A to 25C, involved in the method of forming the semiconductor device of FIGS. 1, 2A and 2B;

FIG. 26B is a fragmentary cross sectional elevation view, taken along a B-B′ line of FIG. 1, illustrating a memory cell in a step, subsequent to the step of FIGS. 25A to 25C, involved in the method of forming the semiconductor device of FIGS. 1, 2A and 2B;

FIG. 26C is a fragmentary cross sectional elevation view in the peripheral circuit area, illustrating a memory cell in a step, subsequent to the step of FIGS. 25A to 25C, involved in the method of forming the semiconductor device of FIGS. 1, 2A and 2B;

FIG. 27A is a fragmentary cross sectional elevation view, taken along an A-A′ line of FIG. 1, illustrating a memory cell in a step, subsequent to the step of FIGS. 26A to 26C, involved in the method of forming the semiconductor device of FIGS. 1, 2A and 2B;

FIG. 27B is a fragmentary cross sectional elevation view, taken along a B-B′ line of FIG. 1, illustrating a memory cell in a step, subsequent to the step of FIGS. 26A to 26C, involved in the method of forming the semiconductor device of FIGS. 1, 2A and 2B;

FIG. 27C is a fragmentary cross sectional elevation view in the peripheral circuit area, illustrating a memory cell in a step, subsequent to the step of FIGS. 26A to 26C, involved in the method of forming the semiconductor device of FIGS. 1, 2A and 2B;

FIG. 28A is a fragmentary cross sectional elevation view, taken along an A-A′ line of FIG. 1, illustrating a memory cell in a step, subsequent to the step of FIGS. 27A to 27C, involved in the method of forming the semiconductor device of FIGS. 1, 2A and 2B;

FIG. 28B is a fragmentary cross sectional elevation view, taken along a B-B′ line of FIG. 1, illustrating a memory cell in a step, subsequent to the step of FIGS. 27A to 27C, involved in the method of forming the semiconductor device of FIGS. 1, 2A and 2B;

FIG. 29A is a fragmentary cross sectional elevation view, taken along an A-A′ line of FIG. 1, illustrating a memory cell in a step, subsequent to the step of FIGS. 28A and 28B, involved in the method of forming the semiconductor device of FIGS. 1, 2A and 2B;

FIG. 29B is a fragmentary cross sectional elevation view, taken along a B-B′ line of FIG. 1, illustrating a memory cell in a step, subsequent to the step of FIGS. 28A and 28B, involved in the method of forming the semiconductor device of FIGS. 1, 2A and 2B;

FIG. 30 is a fragmentary plan view illustrating a semiconductor device in accordance with one embodiment of the present invention;

FIG. 31A is a fragmentary cross sectional elevation view, taken along an A-A′ line of FIG. 1, illustrating a memory cell in a step, subsequent to the step of FIGS. 29A and 29B, involved in the method of forming the semiconductor device of FIGS. 1, 2A and 2B;

FIG. 31B is a fragmentary cross sectional elevation view, taken along a B-B′ line of FIG. 1, illustrating a memory cell in a step, subsequent to the step of FIGS. 29A and 29B, involved in the method of forming the semiconductor device of FIGS. 1, 2A and 2B;

FIG. 32A is a fragmentary cross sectional elevation view, taken along an A-A′ line of FIG. 1, illustrating a memory cell in a step, illustrating another embodiment of the present invention;

FIG. 32B is a fragmentary cross sectional elevation view, taken along a B-B′ line of FIG. 1, illustrating a memory cell in a step, illustrating another embodiment of the present invention;

FIG. 33A is a fragmentary cross sectional elevation view, taken along an A-A′ line of FIG. 1, illustrating a memory cell in a step, illustrating another embodiment of the present invention; and

FIG. 33B is a fragmentary cross sectional elevation view, taken along a B-B′ line of FIG. 1, illustrating a memory cell in a step, illustrating another embodiment of the present invention.

### DETAILED DESCRIPTION OF THE INVENTION

Before describing the present invention, the related art will be explained in detail, in order to facilitate the understanding of the present invention.

In the groove gate transistors in the related art described in JP-A-2006-339476 and JP-A-2007-081095, gate electrodes protrude above the surface of the semiconductor substrate. Deterioration in transistor characteristics may be caused by misaligning the gate electrodes with respect to the groove. Particularly, a DRAM (Dynamic Random Access Memory) may have a configuration in which the gate electrodes are used as word lines and bit lines provided in a direction intersecting with the word lines. In this case, contact plugs connecting the semiconductor substrate to upper layer lines are formed between the word lines formed respectively in a minimum processing dimension. Difficulty in forming the contact plugs is a significant obstacle in miniaturization of the DRAM.

Accordingly, to easily form the contact plugs, embedded gate transistors have been examined. The gate electrodes are completely embedded in grooves without protruding above the surface of the semiconductor substrate. In the embedded gate transistors, the word lines are embedded in the semiconductor substrate. Accordingly, only the bit lines as lines constituting memory cells are positioned above the surface of the semiconductor substrate. There is an advantage that it is possible to reduce the difficulty in processing in a memory cell forming process. The embedded gate transistor includes at least gate electrodes (word lines), a cap insulating film, and bit lines. The gate electrodes (word lines) are formed to be embedded in grooves formed in the semiconductor substrate. A cap insulating film protects upper faces of the gate electrode in the grooves and has an upper face substantially flush with the surface of the semiconductor substrate. The bit lines are formed on the upside with an interlayer insulating film covering the surface of the semiconductor substrate interposed therebetween.

A vertical capacitor such as a cylindrical capacitor provided above the embedded gate transistor. A source region of the embedded gate transistor and the capacitor are connected to each other by a capacitance contact provided to pass through an interlayer insulating film covering the surface of the semiconductor substrate.

However, it is difficult to form capacitors according to miniaturization of the DRAM. Capacitance contact plugs and capacitors are positioned with gaps therebetween to secure insulation between the capacitors, and thus an overlapping margin between the capacitance contact plug and the capacitor is small.

To increase the overlapping margin between the capacitance contact plugs and the capacitors, it is usual to form capacitance contact pads between the capacitance contact plugs and the capacitors. Generally, polysilicon is used for the capacitance contact pad, but it is necessary to form silicide between the capacitance contact pads and the capacitance contact plugs to lower contact resistance.

However, since the capacitance contact pads are provided in alignment with the capacitors, the silicide layer is partially exposed. The exposed part of the silicide layer is disposed on the upper faces of the capacitance contact plugs at a part which is not overlapped with the capacitance contact pads. The exposed part of the silicide layer, which is not covered by the capacitance contact pads, is eluted when the capacitance contact pads are formed or when performing a wet process at the cylinder opening time when the capacitors are formed.

According to the miniaturization process of the DRAM, a dot pattern is formed as the capacitance contact pads in the memory cell area, and a line pattern is used for the same layer of the peripheral circuit area. As a result, it is difficult to simultaneously form the dot pattern and the line pattern in a lithography process manner. For this reason, two photolithography processes are necessary in forming the dot pattern and the line pattern, and costs are increased.

Embodiments of the invention will be now described herein with reference to illustrative embodiments. Those skilled in the art will recognize that many alternative embodiments can be accomplished using the teaching of the embodiments of the present invention and that the invention is not limited to the embodiments illustrated for explanatory purpose.

In one embodiment, a semiconductor device may include, but is not limited to, an insulating film over a silicon substrate, the insulating film having an opening, and a contact plug in the opening, the contact plug having a first top that is lower than an upper face of the insulating film.

In some cases, the semiconductor device may further include, but is not limited to, a contact pad contacting the contact plug. The contact pad comprises the same material as the contact plug.

In some cases, the semiconductor device may further include, but is not limited to, a contact pad having a bottom, the bottom being lower than the upper face of the insulating film.

In some cases, the semiconductor device may further include, but is not limited to, a contact pad contacts the contact plug.

In some cases, the semiconductor device may further include, but is not limited to, a capacitor electrically connected to the contact pad.

In some cases, the semiconductor device may further include, but is not limited to, a contact pad having a bottom, the bottom being lower than a second top of the opening. A first dimension in a first horizontal direction of the bottom of the contact pad is smaller than a second dimension in the first horizontal direction of the opening.

In some cases, the semiconductor device may include, but is not limited to, the contact plug being in contact with the silicon substrate.

In another embodiment, a semiconductor device may include, but is not limited to, a contact plug including a first layer and a second layer. The first layer is over the second layer. The first layer performs as a first part of the contact plug and as a contact pad. The second layer performs as a second part of the contact plug.

In some cases, the semiconductor device may include, but is not limited to, the first layer including metal and the second layer including semiconductor. In some cases, the semiconductor device may include, but is not limited to, the first layer including a first metal layer and a second metal layer.

In some cases, the semiconductor device may include, but is not limited to, the first metal layer covering a first portion of the second metal layer.

In some cases, the semiconductor device may further include, but is not limited to, an insulating film over the contact pad. A second portion of the second metal layer is in contact with the insulating film.

In some cases, the semiconductor device may include, but is not limited to, the contact plug being in contact with the silicon substrate.

In some cases, the semiconductor device may further include, but is not limited to, a capacitor electrically connected to the contact pad.

In some cases, the semiconductor device may further include, but is not limited to, an opening over the silicon substrate. The contact plug partially fills the opening.

In some cases, the semiconductor device may further include, a width of a part of the contact pad in the opening being smaller than a width of the opening.

In still another embodiment, a semiconductor device may include, but is not limited to, a contact plug over a silicon substrate, a first insulating film over the silicon substrate, and a contact pad. A first top of the contact plug is lower than a second top of the first insulating film. A bottom of the contact pad is lower than the second top of the first insulating film.

In some cases, the semiconductor device may include, but is not limited to, a capacitor electrically connected to the contact pad.

In some cases, the semiconductor device may further include, but is not limited to, an opening over the silicon substrate. The contact plug partially fills the opening.

In some cases, the semiconductor device may further include, but is not limited to, a width of a part of the contact pad in the opening is smaller than a width of the opening.

Hereinafter, in one embodiment, a DRAM (Dynamic Random Access Memory) as the semiconductor device will be described. In the drawings used for the following description, to facilitate understanding of the embodiments, illustrations are partially enlarged and shown, and the sizes and ratios of constituent elements are not limited to being the same as the actual dimensions. Materials, sizes, and the like exemplified in the following description are just examples, and the invention is not limited thereto and may be appropriately modified within the scope which does not deviate from the embodiments.

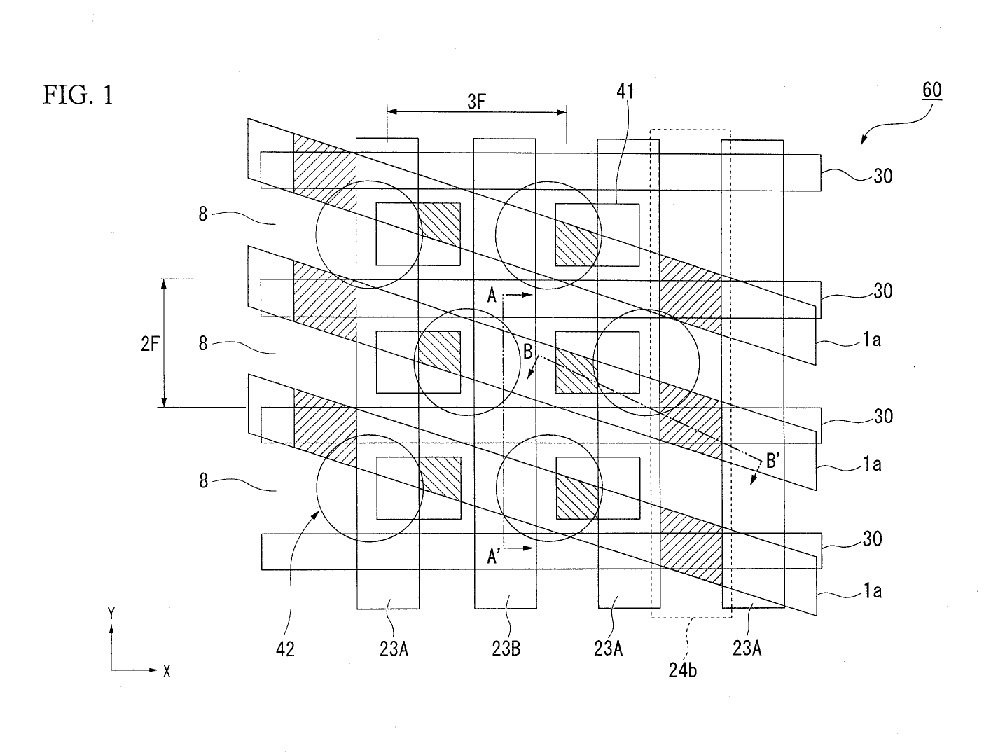

First, a configuration of a DRAM (semiconductor device) according to an embodiment of the invention will be described. The DRAM of the embodiment includes a memory cell area shown in FIG. 1 and a peripheral circuit area (not shown).

As shown in FIG. 1, in the memory cell area of the DRAM (semiconductor device) 60 of the embodiment, a plurality of active regions 1a portioned and surrounded with the element isolation region formed of an STI element isolation film 8 is formed at a predetermined interval in a predetermined direction. Embedded gate electrodes 23A, which are word lines, and an element isolation embedded line 23B are embedded at a predetermined interval in a predetermined direction (Y direction shown in FIG. 1) to longitudinally cross the active regions 1a. A plurality of bit lines 30 is provided in a direction (X direction shown in FIG. 1) perpendicular to the embedded gate electrodes 23A and the embedded line 23B. Memory cells are formed in areas where the embedded gate electrodes 23A intersect the active regions 1a.

The embedded gate electrodes (word lines) 23A and the embedded line 23B have the same structure, but different functions. The embedded gate electrodes 23A are used as gate electrodes of the memory cells. On the contrary, the element isolation embedded line 23B is provided to isolate adjacent transistors from each other over a predetermined potential. That is, the element isolation embedded line 23B is kept at a predetermined voltage to turn off a parasitic transistor, such that the adjacent transistors in the same active region 1a are isolated from each other.

In the whole memory cell area 1000, in which the plurality of memory cells is formed, each memory cell is provided with a capacitor element (not shown). As shown in FIG. 1, such capacitance contact pads 42 are provided at a predetermined interval in the memory cell area 1000 so as not to overlap with each other.

As shown in FIG. 1, the DRAM 60 of the embodiment is provided in 6F² cell disposition where F is a minimum processing size.

Next, the memory cell area constituting the DRAM 60 of the embodiment will be described.

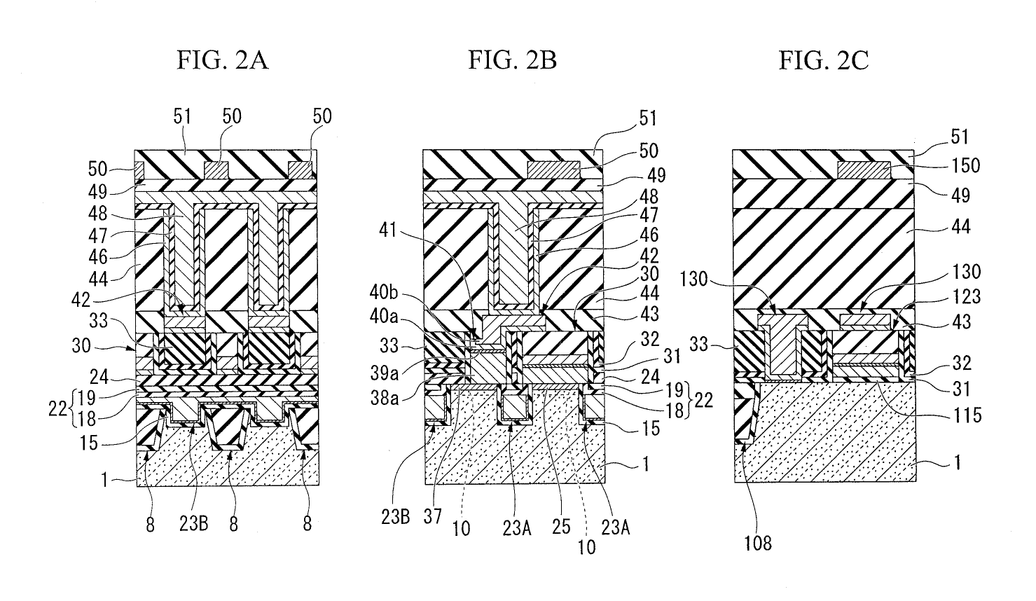

In the memory cell area constituting the DRAM 60 of the embodiment, the plurality of memory cells is formed as described above. As shown in FIG. 2A and FIG. 2B, the memory cell of the embodiment is a laminated structure which includes embedded gate transistors being completely embedded in the semiconductor substrate, capacitors, and wiring layers.

As shown in FIG. 2A and FIG. 2B, the embedded gate transistor schematically includes a semiconductor substrate 1, an STI element separation film 8, an active region la, an embedded gate electrode 23A, a cap insulating film 22, and a bit line 30. The semiconductor substrate 1 has a surface layer formed of silicon. The STI element separation film 8 is formed of an embedded insulating film formed in the semiconductor substrate 1. The active region 1a is partitioned by the STI element isolation film 8. The embedded gate electrode 23A is embedded with a gate insulating film 15 interposed therebetween at the bottom of a gate electrode groove 13. The cap insulating film 22 is embedded in the gate electrode groove 13 to protect the upper face of the gate electrode 23A and having an upper face substantially flush with the surface of the semiconductor substrate 1. The bit line 30 formed above with a first interlayer insulating film (interlayer insulating film) 24 covering the surface of the semiconductor substrate 1 interposed therebetween.

The embedded gate transistor is provided with diffusion regions 25 and 37. The diffusion regions 25 and 37 are formed by injecting ions to the active regions 1a on both widthwise sides of the embedded gate electrode 23A. The embedded gate transistor is connected to the diffusion region 25 and the bit line 30. As shown in FIG. 2A, in the embedded gate transistor of the embodiment, a part of the bottom face of the embedded line 23B is embedded between the adjacent STI element isolation films 8 provided in a lengthwise direction of the embedded line 23B. Accordingly, a thin film silicon portion 14 is formed in a side-wall shape between the STI element isolation film 8 and a partial side face of the bottom face where the embedded line 23B is embedded.

Since the embedded gate electrode 23A and the embedded line 23B have the same structure, the same thin film silicon portion 14 is also provided on a partial bottom face of the embedded gate electrode 23A. The thin film silicon portion 14 can serve as a channel when a potential difference between a source region and a drain region exceeds a threshold value. As described above, the embedded gate transistor of the embodiment constitutes a recess channel type transistor having a channel region such as the thin film silicon portion 14.

Over the substrate in which the embedded gate transistors are formed, capacitors are formed with an insulating layer 33 or the like coating the bit lines 30 formed integrally with the bit contact plugs. Specifically, a capacitance contact pad 42, which is connected to a diffusion region 37 of the embedded gate transistor through a capacitance contact plug 41, is provided on the insulating layer 33. A capacitor is formed over the capacitance contact pad 42. The capacitor includes a lower electrode 46, a capacitance insulating film 47, and an upper electrode 48 provided to pass through a stopper film 43 and a third interlayer insulating film 44,

More specifically, the capacitance contact plug 41 is a laminated structure (hybrid plug) includes a polysilicon layer 38a, a cobalt silicide layer (silicide layer) 39a, and a metal layer including a titanium alloy layer 40a and a tungsten layer 40b, from the semiconductor substrate 1 side. The capacitance contact plug 41 is formed to pass through the insulating layer 33. That is, the upper face of the cobalt silicide layer 39a is coated with the metal layer including the titanium alloy layer 40a and the tungsten layer 40b.

The capacitance contact pad 42 is provided over the insulating layer 33, and has the laminated structure including the titanium alloy layer and the tungsten layer from the insulating layer 33 side. The capacitance contact pad 42 is connected to the upper face of the capacitance contact plug 41 on the bottom face thereof. The capacitance contact pad 42 is connected to the bottom face of the lower electrode 46 constituting the capacitor on the upper face thereof. Accordingly, it is possible to secure a connection margin of the capacitance contact plugs 41 and the capacitors.

In the DRAM 60 of the embodiment, the capacitance contact pads 42 and the metal layer constituting the upper part of the capacitance contact plugs 41 are formed of the same material, and are integrally formed.

The upper face of a non-connection part of the metal layer is recessed from the upper face of the insulating layer 33. The non-connection part is other than the connection part of the bottom face of the capacitance contact pads 42 and the upper face of the metal layer (the titanium alloy layer 40a and the tungsten layer 40b) of the capacitance contact plugs 41. That is, the upper face of the capacitance contact plugs 41 is provided lower than the upper face of the insulating layer 33.

Accordingly, as shown in FIG. 2B, even when the capacitance contact plugs 41 and the capacitance contact pads 42 are positioned with gaps therebetween and connected, it is possible to secure connection reliability of the capacitance contact plugs 41 and the capacitance contact pads 42. In addition, it is possible to suppress a short circuit of the capacitance contact plug 41 of the memory cell adjacent to the lower electrode 46 of the capacitor.

A cylindrical capacitor using only an inner wall of the lower electrode 46 as an electrode is described as an example of the capacitor element of the embodiment, but it is not limited thereto. For example, it may be modified into a crown capacitor using an inner wall and an outer wall of the lower electrode as the electrode.

The wiring layer is provided over the capacitor with a fourth insulating film 49 interposed therebetween, and includes upper metal lines 50 and a protective film 51. In the embodiment, a case where the wiring layer is a one-layer line structure is described as an example, but it is not limited thereto. For example, it may be modified into a multi-layer line structure formed of a plurality of wiring layers and interlayer insulating films.

A transistor is formed for a peripheral circuit in the peripheral circuit area included in the DRAM 60 of the embodiment, as shown in FIG. 2C. The transistor is a different transistor from the transistor described above. The transistor includes at least the gate electrode 123 provided over the semiconductor substrate 1. The transistor also includes the gate insulating film 115 interposed between the gate electrode 123 and the semiconductor substrate 1. The insulating layer 33 coats the gate electrode 123.

In the DRAM 60 of the embodiment, as shown in FIG. 2A to FIG. 2C, the insulating layer 33 is provided over the semiconductor substrate 1 over the memory cell area and the peripheral circuit area. Over the insulating layer 33, the capacitance contact pad 42 is provided in the memory cell area. A wiring layer 130 is provided in the peripheral circuit area. That is, the capacitance contact pad 42 that is the dot pattern of the memory cell area and the wiring layer 130 that is the line pattern of the peripheral circuit area are provided on the same level layer. That is, the capacitance contact pad 42 and the wiring layer 130 are made of the common layer. The wiring layer 130 of the peripheral circuit area is formed of the same material as that of the capacitance contact pads 42 of the memory cell area.

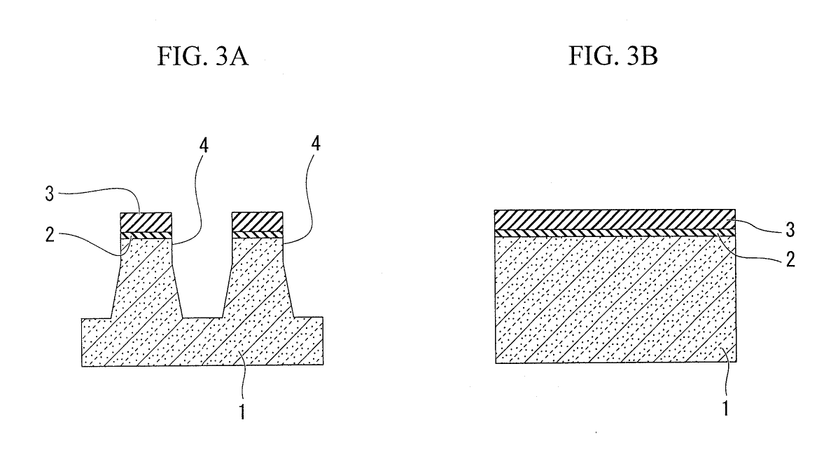

Subsequently, a method of manufacturing the DRAM (semiconductor device) 60 having the above-described configuration will be described with reference to FIG. 3A to FIG. 30. FIG. 3A to FIG. 30 are views for describing the method of manufacturing the DRAM of the embodiment. FIGS. 3A, 4A, 5A, 6A, 7A, 8A, 9A, 10A, 11A, 12A, 13A, 14A, 15A, 16A, 17A, 18A, 19A, 20A, 21A, 22A, 23A, 24A, 25A, 26A, 27A, 28A, and 29A each show a cross-sectional structure of the part taken along the line A-A′ shown in FIG. 1, and FIGS. 3B, 4B, 5B, 6B, 7B, 8B, 9B, 10B, 11B, 12B, 13B, 14B, 15B, 16B, 17B, 18B, 19B, 20B, 21B, 22B, 23B, 24B, 25B, 26B, 27B, 28B, and 29B each show a cross-sectional structure of the part taken along the line B-B′ shown in FIG. 1.

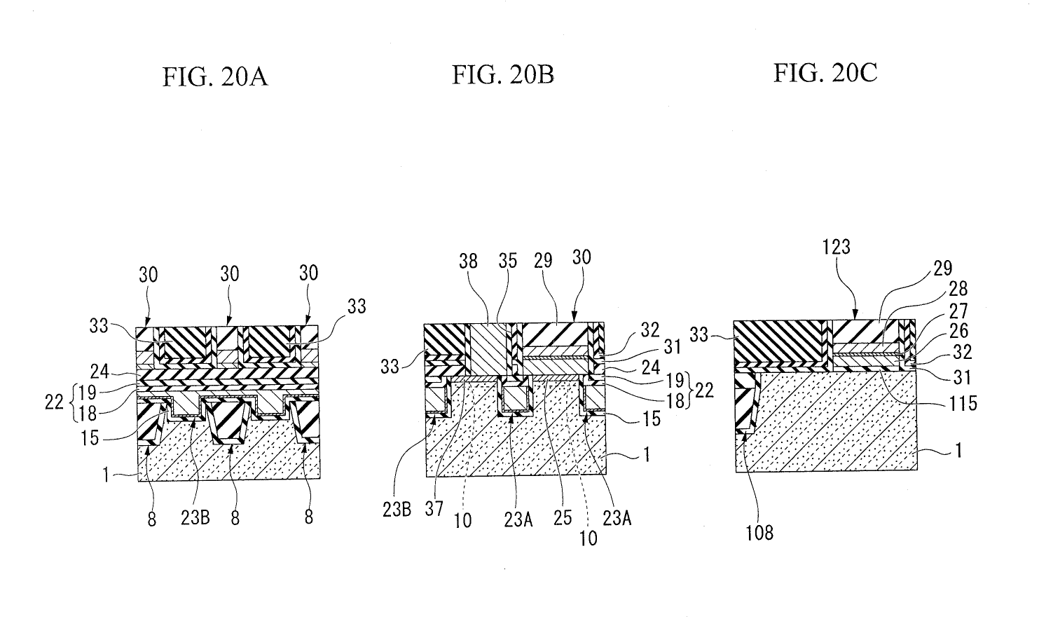

FIGS. 20C, 21C, 22C, 23C, 24C, 25C, 26C, and 27C each show cross-sectional views in the peripheral circuit area.

The method of manufacturing the DRAM (semiconductor device) 60 of the embodiment includes the following process. An element isolation region is formed. An embedded gate electrode is formed. A bit line is formed. A capacitance contact plug is formed. A capacitor is formed. A wiring layer is formed.

More specifically, the method of manufacturing the DRAM 60 of the embodiment includes the following processes. An embedded gate electrode is formed in the memory cell area of the semiconductor substrate. A bit contact and a bit line are formed in the memory cell area on the upper face of the semiconductor substrate. A gate electrode is formed in the peripheral circuit area. An insulating layer is formed over the semiconductor substrate over the memory cell area and the peripheral circuit area. A contact hole is formed to pass through the insulating layer of the memory cell area. The inside of the contact hole is filled with polysilicon. An etch-back process is performed to recess the upper face of the polysilicon from the upper face of the insulating layer to form a polysilicon layer. A silicide layer is formed over the polysilicon layer in the contact holes. The inside of the contact hole is filled with a metal material. A metal film is formed over the insulating layer over the memory cell area and the peripheral circuit area. The metal film is patterned. In the process of patterning the metal film, the metal layer coating the upper face of the silicide layer and the capacitance contact pad are formed in the memory cell area and the wiring layer is formed integrally in the peripheral circuit area. The upper face of the metal layer other than the connection part of the bottom face of the capacitance contact pads and the upper face of the metal layer is recessed from the upper face of the insulating layer.

Hereinafter, the processes will be described in detail.

(Process of Forming Element Isolation Regions)

First, the element isolation region for isolating an active region 1a are formed on a surface of a silicon substrate (semiconductor substrate) 1. As shown in FIG. 3A and FIG. 3B, for example, the element isolation region is formed by sequentially laminating a silicon oxide film (SiO₂) 2 and a mask silicon nitride film (Si₃N₄) 3 over the P type silicon substrate (semiconductor substrate) 1. Then, patterning processes of a silicon nitride film 3, a silicon nitride film 2, and the silicon substrate 1 are performed in sequence using a photolithography technique and a dry etching technique to form element isolation grooves (trenches) 4 for partitioning the active regions 1a over the silicon substrate 1. The silicon surface, which becomes the active regions 1a, of the silicon substrate 1 is covered with the mask silicon nitride film 3.

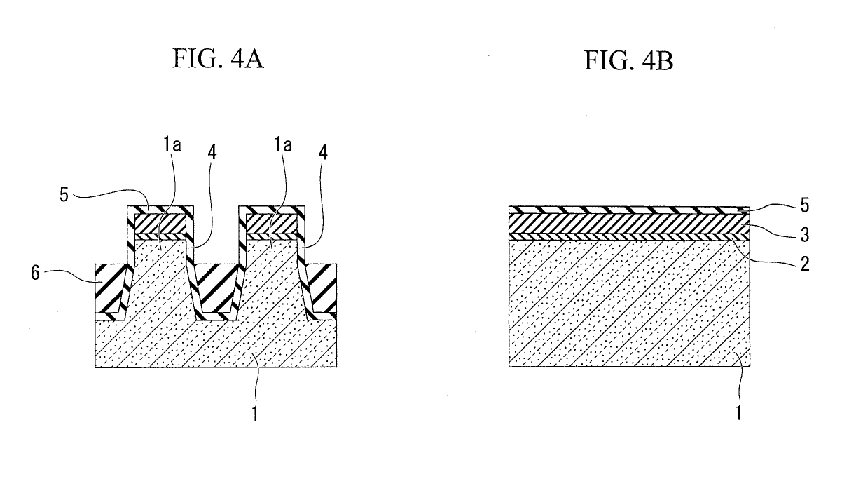

Then, as shown in FIG. 4A and FIG. 4B, a silicon oxide film 5 is formed on the surface of the silicon substrate 1 exposed into the element isolation grooves 4. Specifically, the silicon oxide film 5 is formed by thermal oxidation on the surface of the silicon oxide film 2 and the silicon nitride film 3 coating the active regions 1a of the silicon substrate 1 together with the surface of the silicon substrate 1 in the element isolation grooves 4. Then, silicon nitride is laminated to fill the insides of the element isolation grooves 4, etch-back process is performed. A silicon nitride film 6 is allowed to remain at the bottom in the element isolation grooves 4.

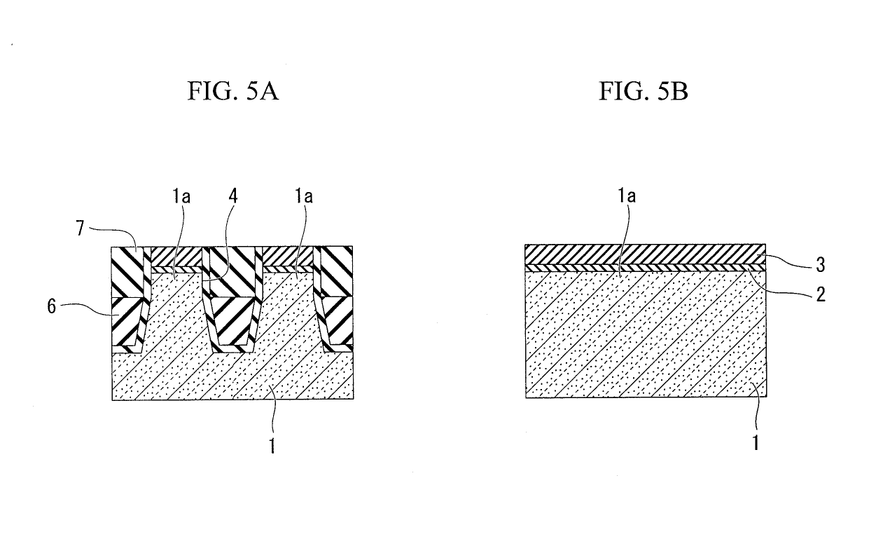

Then, as shown in FIG. 5A and FIG. 5B, silicon oxide is laminated to fill the insides of the element isolation grooves 4 by, for example, a CVD method. Subsequently, CMP is performed to planarize the surface of the substrate until the mask silicon nitride film 3 is exposed, thereby forming a silicon oxide film 7. As described above, the insides of the element isolation grooves 4 are filled with the 2-layer structure of the lower-layer silicon nitride film 6 and the upper layer silicon oxide film 7. It is possible to reliably fill the insides of the element isolation grooves 4 with the insulating film even when widths of the element isolation grooves 4 are very small.

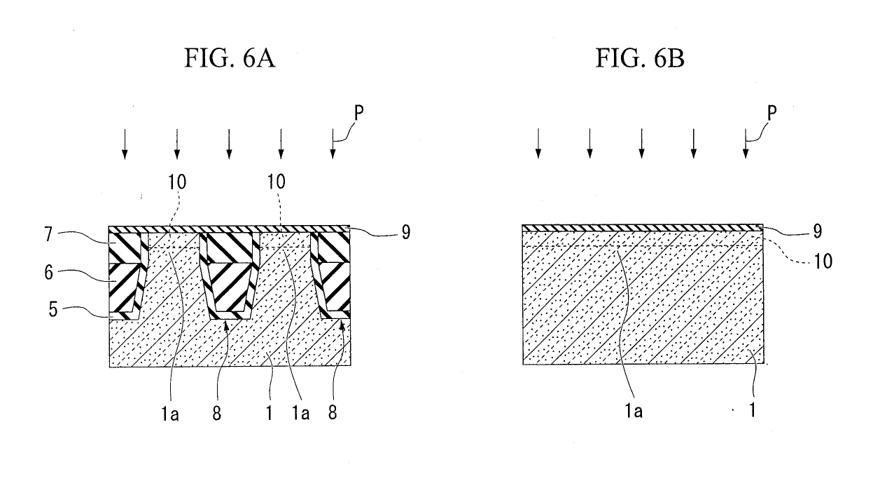

Then, as shown in FIG. 6A and FIG. 6B, the mask silicon nitride film 3 and the silicon oxide film 2 are removed by, for example, wet etching. Thus, the surface (i.e., the surface of the silicon oxide film 7) of the element isolation groove 4 and the surface of the silicon substrate 1 become substantially flush with each other. In such a manner, STI (Shallow Trench Isolation) element isolation film 8 constituting the element isolation region is formed. The active regions 1a are partitioned in the silicon substrate 1 by the element isolation region.

Then, an impurity diffusion layer is formed on the surface of the silicon substrate 1. The impurity diffusion layer is formed as follows. First, as shown in FIG. 6A and FIG. 6B, a silicon oxide film 9 is formed on the surface of the exposed silicon substrate 1 by thermal oxidation. Then, low-concentration N type impurities (phosphorus, etc.) are injected to the active regions 1a of the silicon substrate 1 by ion injection, using the silicon oxide film 9 as a mask. In such a manner, an N type impurity diffusion layer 10 is formed in the vicinity of the surface of the silicon substrate 1. The N type impurity diffusion layer 10 serves as a part of source and drain regions of the transistors.

(Process of Forming Embedded Gate Electrodes)

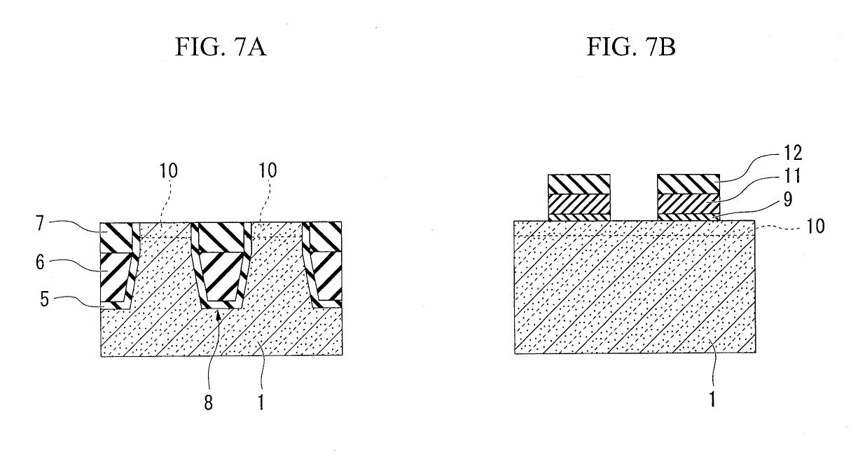

Next, an embedded gate electrode (word line) is formed. The embedded gate electrode is formed as follows. First, as shown in FIG. 7A and FIG. 7B, a mask silicon nitride film 11 and a carbon film (amorphous carbon film) 12 are sequentially laminated over the silicon oxide film 9. The carbon film 12, the silicon nitride film 11, and the silicon oxide film 9 are sequentially patterned to form a hard mask for forming a gate electrode groove (trench).

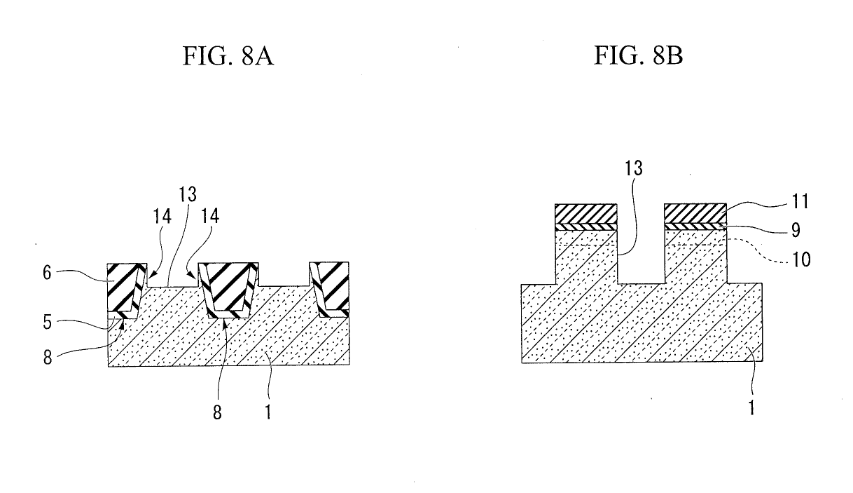

Then, as shown in FIG. 8A and FIG. 8B, the silicon substrate 1 exposed from the hard mask is etched by dry etching, and thus the gate electrodes groove (trench) 13 is formed. The gate electrodes grooves 13 are formed as a linear pattern extending in a predetermined direction (e.g., the Y direction in FIG. 1) intersecting with the active regions 1a. As shown in FIG. 8A, when the gate electrode grooves 13 are formed, part of the silicon layer is etched deeper than part of the STI element isolation film 8 such that the surface of the STI element isolation film 8 is higher than the silicon substrate 1. Accordingly, a thin film silicon portion 14 having a side-wall shape remains on the side parts of the gate electrode grooves 13 being in contact with the STI element isolation films 8. The thin film silicon portion 14 serves as the channel region of the transistor.

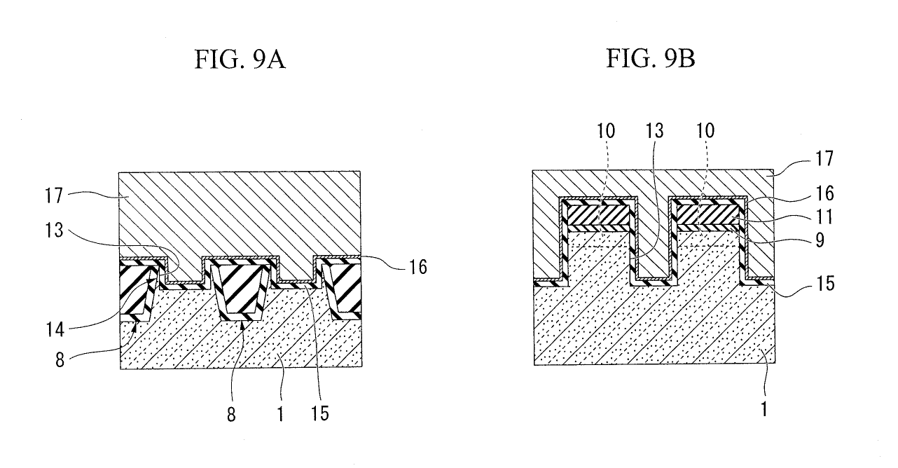

Then, as shown in FIG. 9A and FIG. 9B, a gate insulating film 15 is formed to cover the inner wall face of the gate electrode groove 13 and the surface of the substrate. As the gate insulating film 15, for example, a silicon oxide film formed by thermal oxidation or the like may be used. Then, gate electrode materials are sequentially laminated over the gate insulating film 15 to fill the gate electrodes 13. Specifically, using titanium nitride (TiN) and tungsten (W) as the gate electrode materials, for example, the gate electrode grooves 13 are filled with a titanium nitride film 16 and a tungsten film 17.

In the method of forming the gate electrode in the related art, conductive polysilicon has been used at a part being in contact with the gate insulating film 15. However, when the polysilicon is used for the miniaturized embedded gate electrodes, a resistance of the gate electrodes becomes high, which is not preferable. Accordingly, in the embodiment, the gate electrode grooves 13 are filled only with titanium nitride and tungsten without using polysilicon.

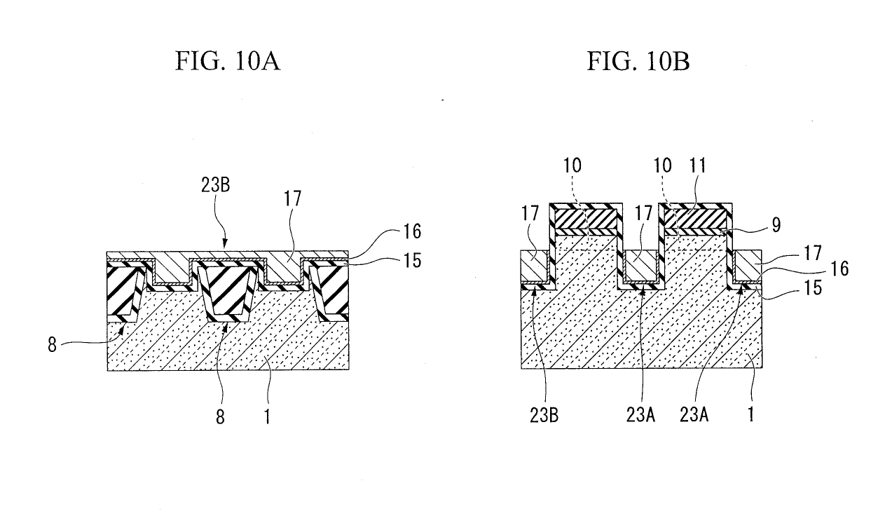

Then, as shown in FIG. 10A and FIG. 10B, etch-back process is performed on the titanium nitride film 16 and the tungsten film 17 formed to fill the inside of the gate electrode groove 13. The titanium nitride film 16 and the tungsten film 17 are allowed to remain only at the bottoms of the gate electrode grooves 13. In such a manner, the embedded gate electrode (word line) 23A and the embedded line 23B are formed to fill the inside of the gate electrode groove 13 formed in the silicon substrate 1. To embed the gate electrode, the degree of the etch-back process is adjusted such that the upper face of the tungsten film 17 constituting the embedded gate electrodes 23A in the gate electrode grooves 13 is positioned lower (deeper) than the silicon layer of the silicon substrate 1.

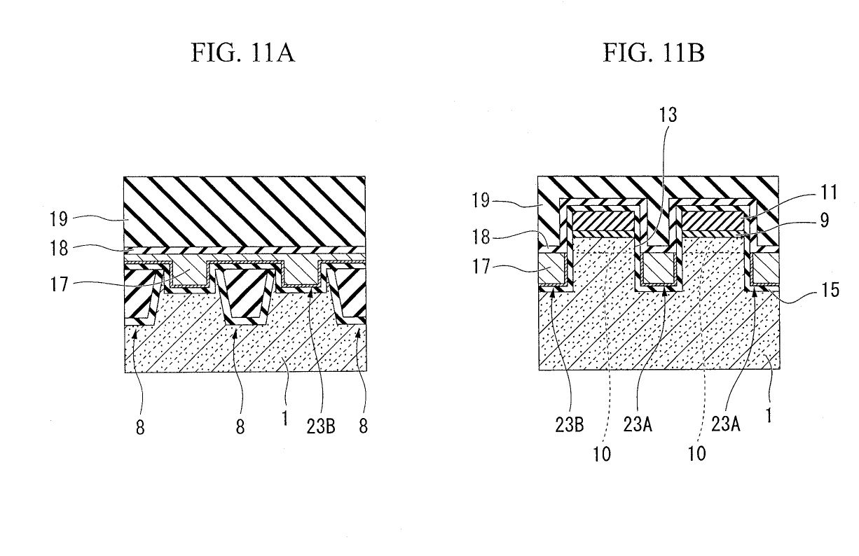

Then, as shown in FIG. 11A and FIG. 11B, a linear film 18 is formed of, for example, a silicon nitride film or the like to cover the upside of the remaining tungsten film 17 and the inner walls of the gate electrodes grooves 13. Then, an embedded insulating film 19 is formed over the linear film 18. As the embedded insulating film 19, for example, a silicon oxide film formed by a CVD method, an SOD (Spin On Dielectric) film that is a coating film, and a laminated film thereof may be used. When the SOD film is used as the embedded insulating film 19, the SOD film is applied onto the linear film 18. Then an annealing process is performed in an atmosphere of high temperature water vapor (H₂O) to reform it into a solid film.

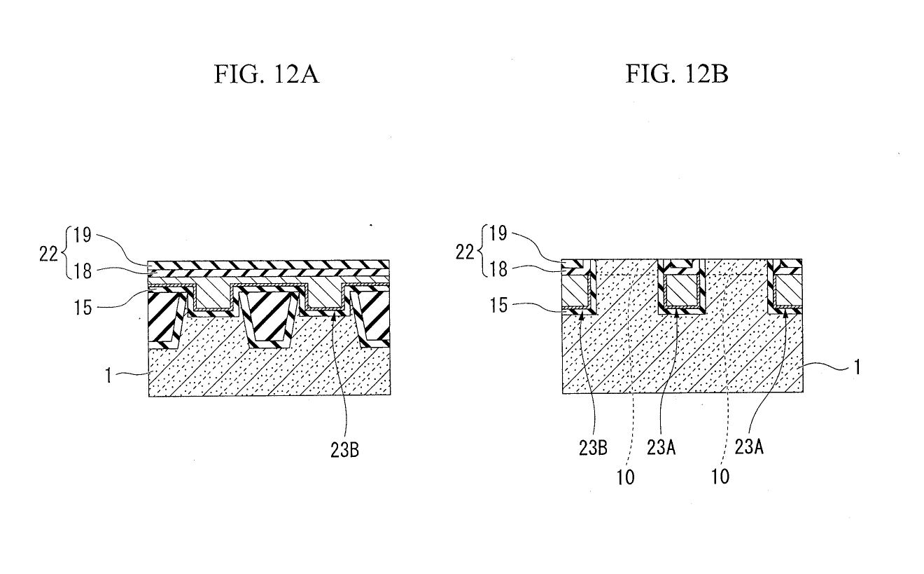

Then, as shown in FIG. 12A and FIG. 12B, a CMP process is performed, the surface of the substrate is planarized until the linear film 18 formed over the mask silicon nitride film 11 is exposed. Thereafter, the mask silicon nitride film 11 and a part of the embedded insulating film 19 and the linear film 18 are removed by etching (etch-back process) to expose the silicon surface of the silicon substrate 1. In such a manner, a cap insulating film 22 formed of the linear film 18 and the embedded insulating film 19 is formed above the embedded gate electrode (word line) 23A and the embedded line 23B. As described above, to form the cap insulating film 22 by performing etch-back process of the silicon nitride film 11 and a part of the embedded insulating film 19 and the liner film 18, it is preferable to perform etching such that the height of the surface of the embedded insulating film 19 (see FIG. 12A) is substantially the same as the height of the silicon surface of the silicon substrate 1 (see FIG. 12B).

(Process of Forming Bit Lines)

Then, bit lines 30 are formed. In the forming of the bit lines 30, a first interlayer insulating film 24 is formed to cover the surface of the silicon substrate 1 and the surface of the cap insulating film 22.

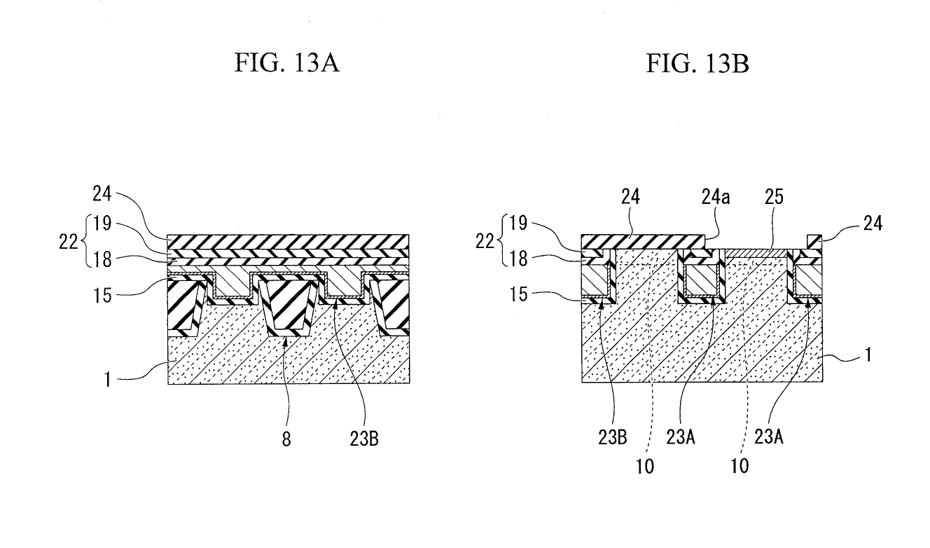

Next, as shown in FIG. 13A and FIG. 13B, a part of the first interlayer insulating film 24 is removed using a photolithography technique and a dry etching technique so as to form a bit contact opening portion 24a. For example, as shown in FIG. 1, the bit contact opening portion 24a is formed as a linear opening pattern 24b extending in the same direction (the Y direction shown in FIG. 1) as that of the word lines 23A. At a part where the bit contact opening pattern 24b intersects with the active region 1a, a silicon surface of the silicon substrate 1 is exposed from the bit contact opening portion 24a as shown in FIG. 13B.

Then, as shown in FIG. 13A and FIG. 13B, using the first insulating film 24 as a mask, N type impurities such as arsenic are injected by ion injection into the surface of the silicon substrate 1 exposed from the bit contact opening portion 24a. Accordingly, an N type impurity diffusion layer is formed in the vicinity of the surface of the silicon substrate 1. The N type impurity diffusion layer becomes a diffusion region 25 serving as one of source and drain regions (in the embodiment, a drain region) of the transistor. In the diffusion region 25 of the embodiment, it is preferable that an amount of ion injection (N⁺) is made slightly larger than an amount (N) of ion injection at the time of forming the N type impurity diffusion layer 10 to provide a concentration gradation, in order to adopt an LDD structure (Lightly Doped Drain).

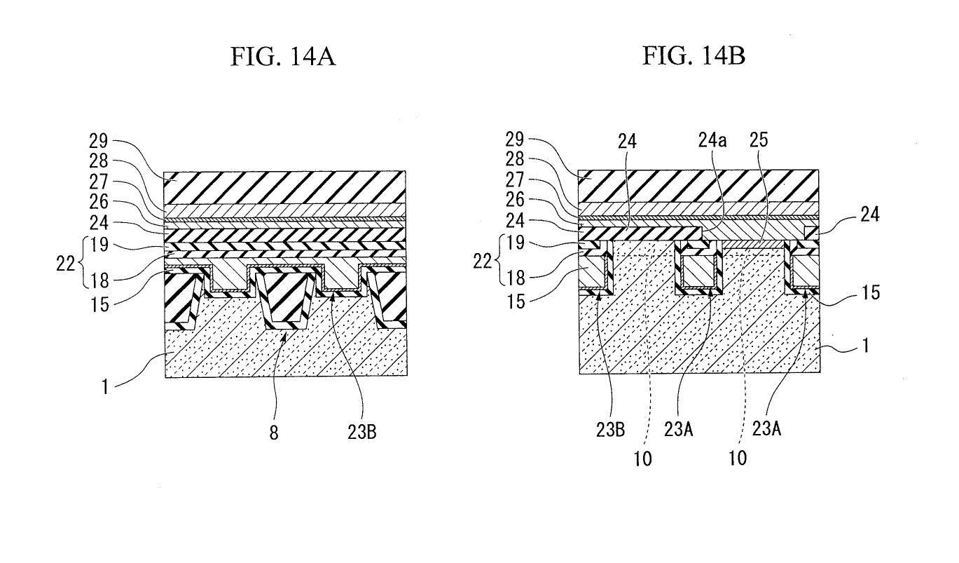

Then, as shown in FIG. 14A and FIG. 14B, a polysilicon containing N type impurities such as phosphorous or the like is deposited over the first interlayer insulating film 24 to form a polysilicon film 26. In this case, the polysilicon is reliably embedded in the bit contact opening portion 24a. Then, tungsten silicide (WSi), tungsten, and silicon nitride are sequentially deposited over the polysilicon film 26 to respectively form a tungsten silicide film 27, a tungsten film 28, and a silicon nitride film 29.

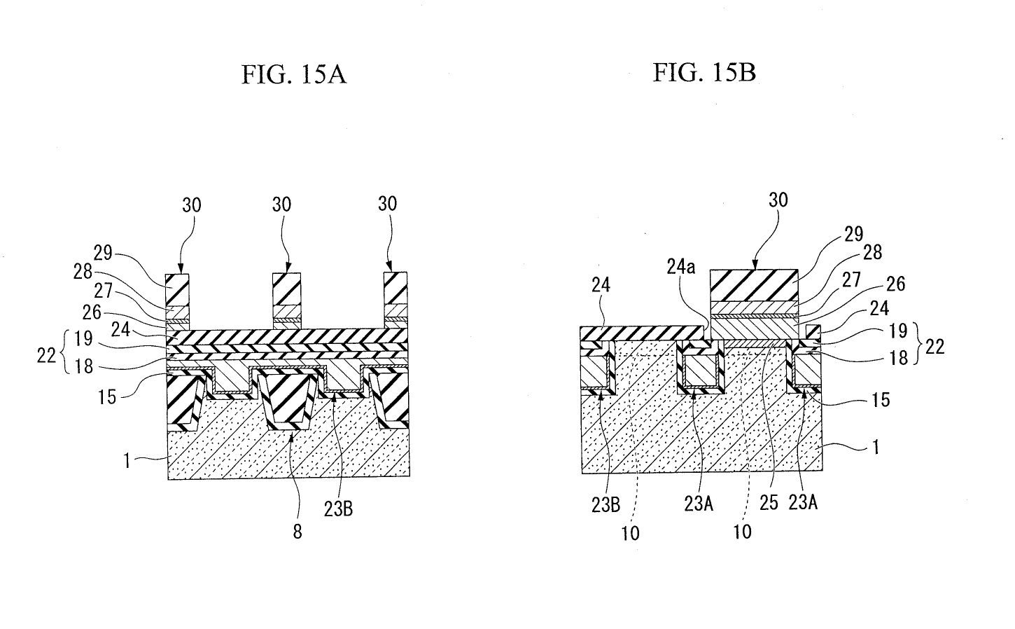

Then, as shown in FIG. 15A and FIG. 15B, a stack of the polysilicon film 26, the tungsten silicide film 27, the tungsten film 28, and the silicon nitride film 29 is linearly patterned to form the bit line 30.

The bit line 30 is connected to the diffusion region 25 which becomes a part of the source and drain regions in the bit contact opening portion 24a. That is, the polysilicon film 26 constituting the bit line 30 is connected to the diffusion region 25 formed at the surface part of the silicon substrate 1 exposed from the bit contact opening portion 24a. As described above, the bit line 30 of the embodiment also serve as contact plugs connected to the diffusion region 25 which becomes a part of the source and drain regions. In the manufacturing method of the embodiment, the bit line 30 also serving as the contact plugs is formed (integrally formed) by one lithography process.

In the embodiment, the bit contact plugs and the bit lines are formed by one lithographic printing and dry etching. Accordingly, since misalignment of the bit contact plugs and the bit lines, such as a diameter of the bit contact plugs becoming larger than a bit line width, does not occur, it is possible to prevent formation of a short circuit with the other conductor.

The bit line 30 is formed in a pattern extending in an intersecting direction (the X direction shown in FIG. 1) of the word line 23A and the embedded line 23B. In the example shown in FIG. 1, the bit line 30 having a linear shape perpendicular to the word line 23A is shown, but it is not limited thereto. For example, the bit line 30 may be formed in a partially curved shape.

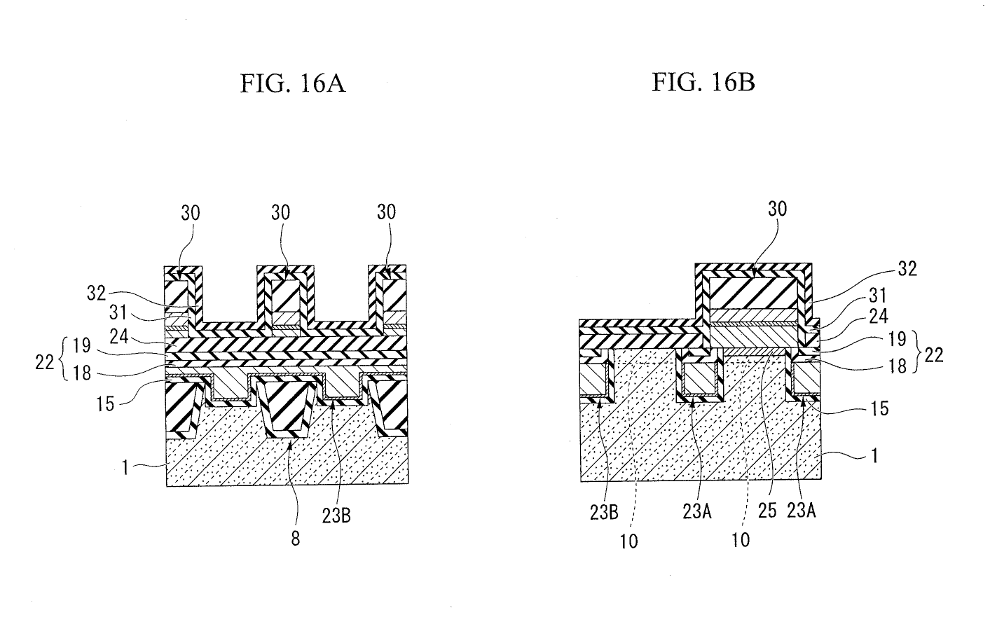

Then, as shown in FIG. 16A and FIG. 16B, the silicon nitride film 31 is formed over the first interlayer insulating film 24 to cover the surface of the bit line 30, and then a linear film 32 is laminated to cover the surface of the silicon nitride film 31. As the linear film 32, for example, a silicon nitride film (Si₃N₄), a silicon oxynitride (SiON), or the like may be used.

As described above, the DRAM 60 of the embodiment is provided with the peripheral circuit area (not shown) in the peripheral area of the memory cell area shown in FIG. 1. As shown in FIG. 2C, when, for example, a planar MOS transistor is formed as the transistor for peripheral circuits in the peripheral circuit area, it is possible to form the gate electrode 123 of the transistor for peripheral circuits while forming the bit line 30. The laminated film formed of the silicon nitride film 31 and the liner film 32 covering the side faces of the bit line 30 may be used as a part of the side walls of the gate electrode 123 in the transistor for peripheral circuit.

(Process of Forming Capacitance Contact Plugs and Capacitance Contact Pads)

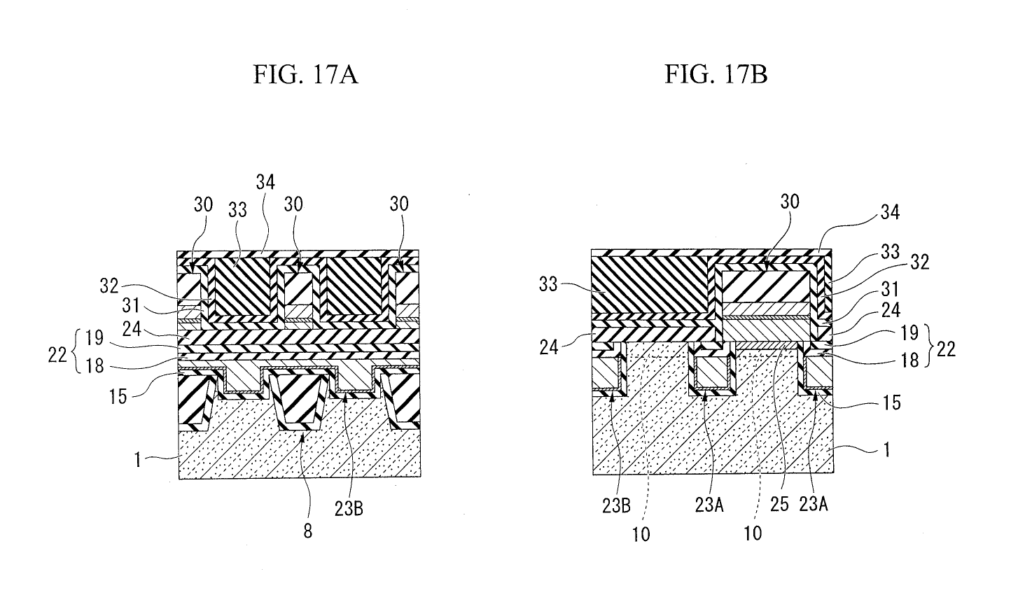

Next, the capacitance contact plug 41 and the capacitance contact pad 42 are formed. Specifically, as shown in FIG. 17A and FIG. 17B, SOD is applied onto the liner film 32 to fill a space between the bit lines 30. An annealing process is performed in an atmosphere with water vapor (H₂O) to reform the SOD into a solid film, and an SOD film (insulating film) 33 is formed. Then, CMP is performed until the upper face of the liner film 32 is exposed to planarize the surface of the substrate. A second interlayer insulating film 34 is formed to cover the SOD film 33 and the upper face of the liner film 32. As the second interlayer insulating film 34, for example, a silicon oxide film formed by the CVD method may be used.

In the manufacturing method of the embodiment, the SOD film 33 is simultaneously formed over the memory cell area and the peripheral circuit area (not shown) over the substrate.

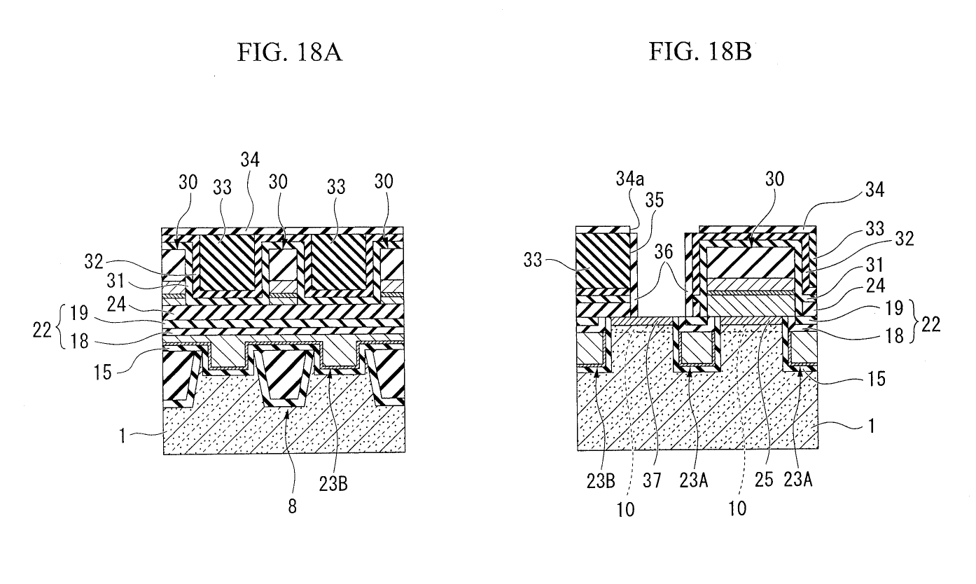

Then, as shown in FIG. 18A and FIG. 18B, a capacitance contact opening portion (contact hole) 35 is formed using a photolithography technique and a dry etching technique. The capacitance contact opening portion 35 is formed by an SAC (Self Alignment Contact) method using the silicon nitride film 31 and the liner film 32 formed as the side walls of the bit lines 30.

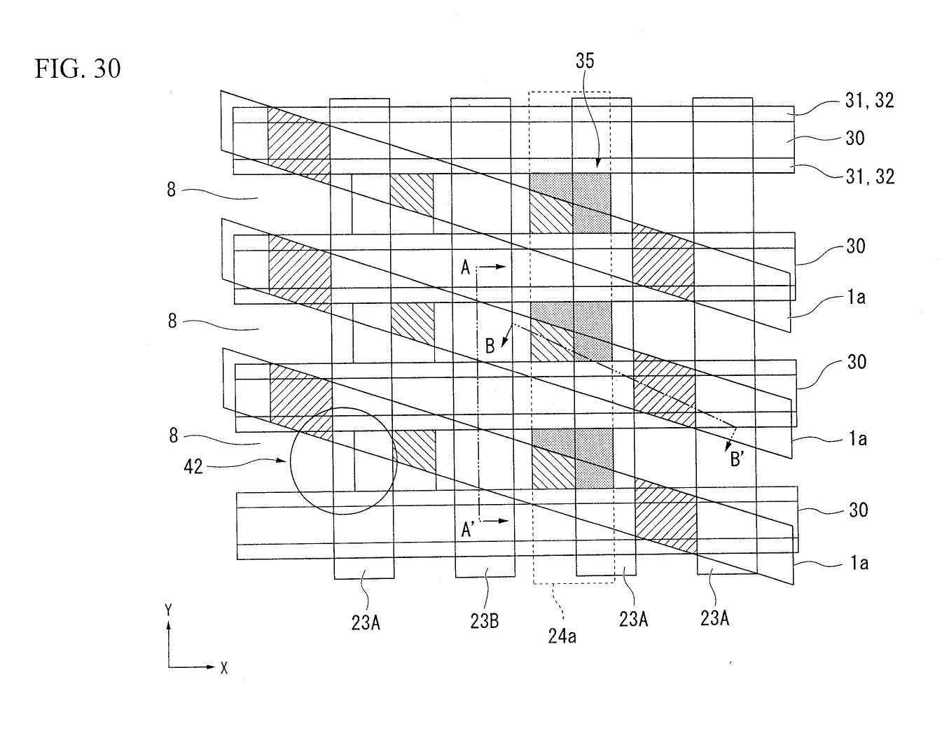

Specifically, as shown in FIG. 30, first, a linear opening pattern 34a extending, for example, in the same direction (the Y direction shown in FIG. 30) as that of the word line 23A is formed in the second interlayer insulating film 34. In the case of forming the opening pattern 34a, an opening is self-aligned in the SOD film 33 by dry-etching in a width direction of which is regulated in the silicon nitride film 31 and the linear film 32 formed on the side face of the bit lines 30 when the SOD film 33 is dry-etched with the second insulating film 34. Then, the linear film 32, the silicon nitride film 31, and the first interlayer insulating film 24 which are exposed from the opening are sequentially removed by etching, to form the capacitance contact opening portion 35.

As shown in FIG. 30, at the part where the capacitance contact opening portion 35 overlaps with the active region 1a, the silicon surface of the silicon substrate 1 is exposed from the capacitance contact opening portion 35 as shown in FIG. 18B.

Then, as shown in FIG. 18A and FIG. 18B, side walls (SW) 36 formed of, for example, silicon nitride film are formed over the inner wall portions of the capacitance contact opening portion 35. Then, N type impurities such as phosphorous are injected by ion injection to the surface of the silicon substrate 1 exposed from the capacitance contact opening portion 35, using the second interlayer insulating film 34 as a mask. Accordingly, an N type impurity diffusion layer is formed in the vicinity of the silicon surface of the silicon substrate 1. The N type impurity diffusion layer becomes a diffusion region 37 serving as the other of the source and drain regions (source region in the embodiment) of the transistor.

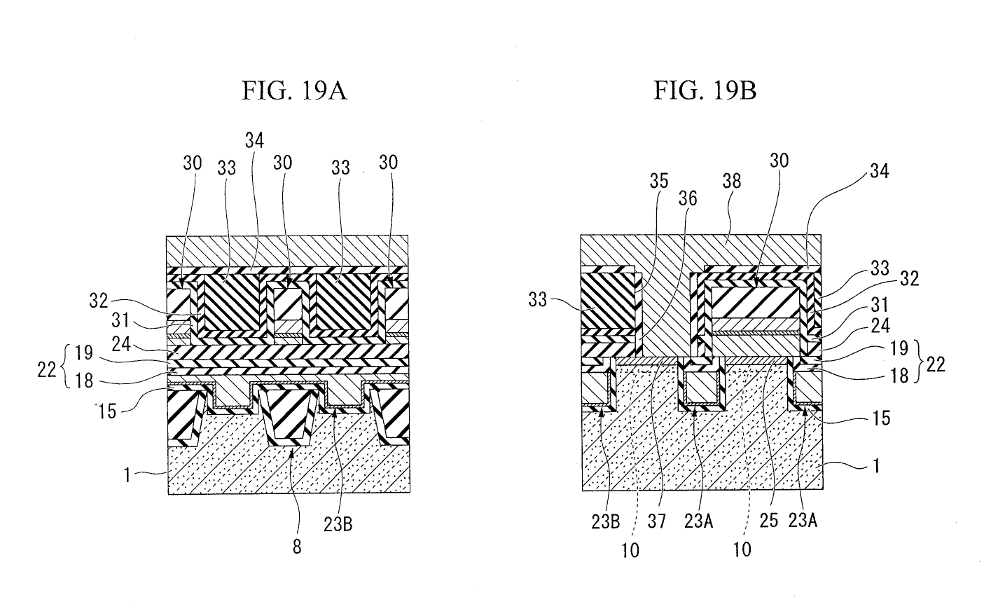

Then, as shown in FIG. 19A and FIG. 19B, a polysilicon 38 containing phosphorous is deposited over the second interlayer insulating film 34 to fill the inside of the capacitance contact opening portion 35.

In addition, the polysilicon 38 is laminated over the peripheral circuit area (not shown).

Then, as shown in FIG. 20A and FIG. 20B, the surface is planarized by CMP until the surfaces of the silicon nitride film 29 and the SOD film 33 are exposed, such that the polysilicon remains in the capacitance contact opening portions 35.

As shown in FIG. 20C, even in the peripheral circuit area, the surface is planarized by the CMP until the surfaces of the silicon nitride film 29 and the SOD film 33 are exposed, such that the polysilicon 38 is removed.

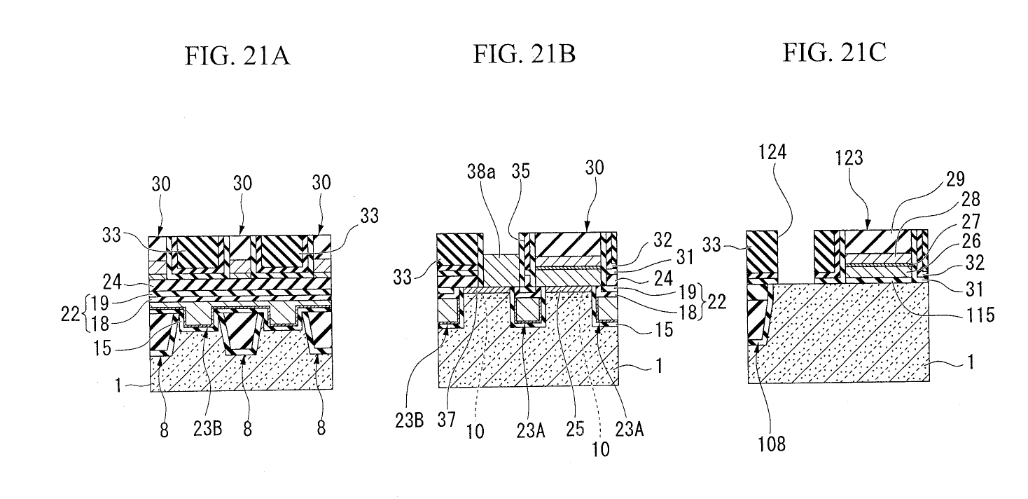

Then, as shown in FIG. 21B, a polysilicon layer 38a is formed by an etch-back process to recess the upper face of the polysilicon from the upper face of the SOD film (insulating layer) 33.

The amount of recession from the upper face of the SOD film 33 of the polysilicon layer 38a may be appropriately selected by thicknesses of a cobalt silicide layer 39a, a titanium alloy layer 40a, and a tungsten layer 40b to be described later.

Then, as shown in FIG. 21C, a contact hole 124 is formed to pass through the SOD film 33 of the peripheral circuit area. The surface of the silicon substrate 1 is exposed from the contact hole 124.

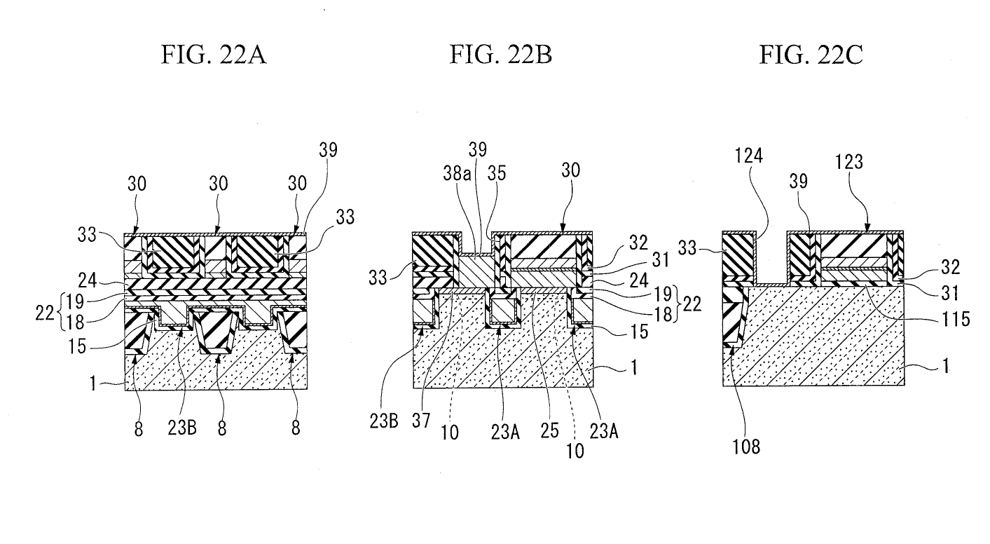

Then, as shown in FIG. 22A to 22C, the cobalt (Co) film 39 is formed over the substrate over the memory cell area and the peripheral circuit area by a sputtering method or the like.

In this case, as shown in FIG. 22B, in the memory cell area, the inside of the capacitance contact opening portions 35 and the upper face of the polysilicon layer 38a are coated with the cobalt film 39.

As shown in FIG. 22C, in the peripheral circuit area, the inside of the contact hole 124 and the surface of the exposed silicon substrate 1 are coated with the cobalt film 39.

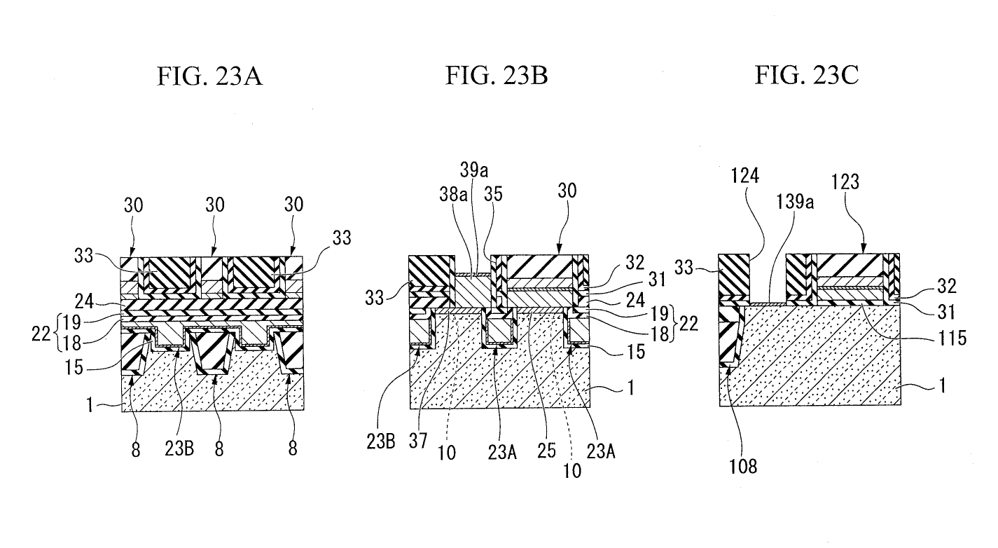

Then, a heat treatment is performed to silicide the cobalt film 39, and then a non-silicided portion of the cobalt film 39 is removed by an etching process. Accordingly, as shown in FIG. 23B, in the memory cell area, a cobalt silicide (CoSi) layer 39a is formed on the upper face of the polysilicon layer 38a in the capacitance contact opening portion 35. As shown in FIG. 23C, the cobalt silicide layer 139a is formed on the silicon surface in the contact hole 124 in the peripheral circuit area.

Then, the inside of the capacitance contact opening portion 35 of the memory cell area and the inside of the contact hole 124 of the peripheral circuit area are filled with a metal material. A metal film is formed over the SOD film 33 over the memory cell area and the peripheral circuit area.

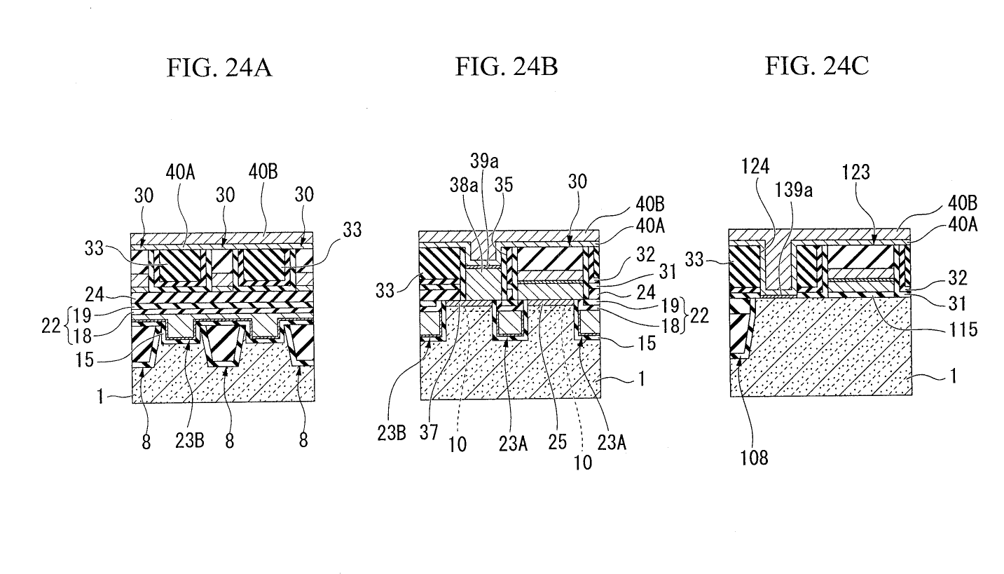

Specifically, as shown in FIG. 24A to FIG. 24C, titanium nitride (TiN) and titanium (Ti) are sequentially laminated over the substrate over the memory cell area and the peripheral circuit area to form a titanium laminated film 40A. A tungsten (W) film 40B is laminated over the titanium laminated film 40A.

In this case, as shown in FIG. 24B, in the memory cell area, the inside of the capacitance contact opening portion 35 and the upper face of the cobalt silicide layer 39a are coated with the titanium laminated film 40A formed by sequentially laminating titanium nitride and titanium. The tungsten film 40B is formed to fill the inside of the capacitance contact opening portion 35.

As shown in FIG. 24C, in the peripheral circuit area, the inside of the contact hole 124 and the upper face of the cobalt silicide layer 139a are coated with the titanium laminated film 40A. The tungsten film 40B is formed to fill the inside of the contact hole 124.

In the manufacturing method of the embodiment, a 3-layer structure of titanium nitride, titanium, and tungsten is exemplified as the metal material, but it is not limited thereto. For example, a single-layer structure of only tungsten may be applied, and a multi-layer of 2 or more layers may be applied.

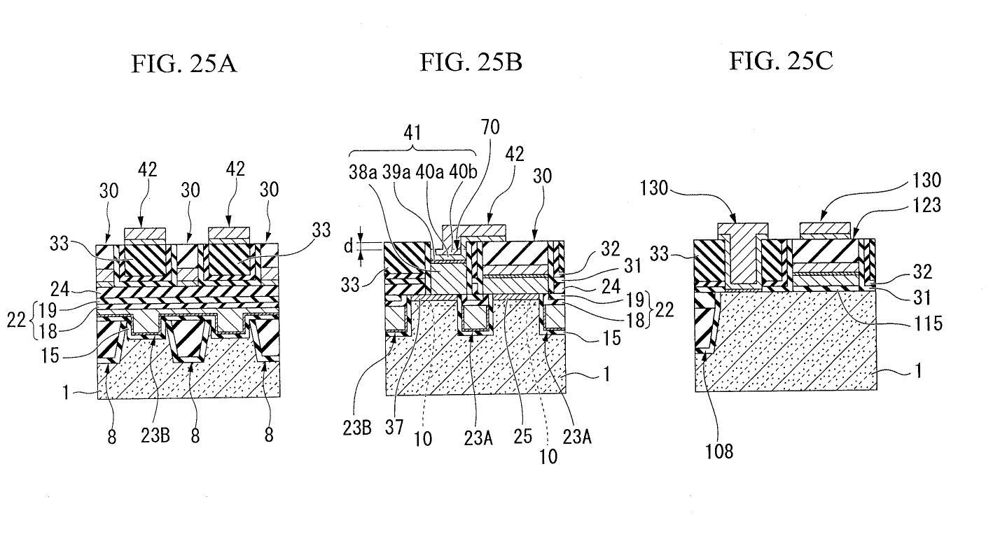

Then, as shown in FIG. 25A to FIG. 25C, the titanium laminated film 40A and the tungsten film 40B formed over the substrate of the memory cell area and the peripheral circuit area are integrally patterned.

According to the manufacturing method of the embodiment, in the memory cell area, as shown in FIG. 25A and FIG. 25B, the capacitance contact plug 41 and the capacitance contact pad 42 can be integrally formed (simultaneously formed).

Here, the capacitance contact plug 41 is bounded with the capacitance contact pad 42 by a broken line 70. The capacitance contact plug 41 has the top which is lower than the upper surface of the SOD film 33. The capacitance contact pad 42 has the bottom which is lower than the upper surface of the SOD film 33. The capacitance contact plug 41 has the top which is lower than the top of the contact hole 124. The capacitance contact pad 42 has the bottom which is lower than the top of the contact hole 124. There is a difference d between the top of capacitance contact plug 41 and the upper surface of the SOD film 33. The capacitance contact plug 41 partially fills the contact hole 124. The capacitance contact pad 42 has a lower portion which is positioned in the contact hole 124. The capacitance contact plug 41 contacts the capacitance contact pad 42. The capacitor shown in FIGS. 2A and 2B is electrically connected to the capacitance contact pad 42. The lower portion of the capacitance contact pad 42 has a dimension defined in a horizontal direction which is parallel to the B-B′ line in FIG. 1. The dimension is smaller than the dimension of the contact hole 124, defined in the horizontal direction parallel to the B-B′ line in FIG. 1. The capacitor contact plug 41 includes a first layer and a second layer. The first layer is over the second layer. The first layer performs as a first part of the capacitor contact plug 41 and as a capacitor contact pad 42. The second layer performs as a second part of the capacitor contact plug 41. The first layer includes the titanium alloy layer 40a and a tungsten layer 40b over the titanium alloy layer 40a. The second layer includes the polysilicon layer 38a and the cobalt silicide layer 39a over the polysilicon layer 38a. A portion of the second tungsten layer 40b is in contact with the third interlayer insulating film 44.

A dimension in a first horizontal direction of the bottom of the contact pad is smaller than a second dimension in the first horizontal direction of the opening.

As shown in FIG. 1, it is necessary to form the capacitance contact pads 42 in the memory cell area at uniform intervals. For this reason, as shown in FIG. 25B, the capacitance contact pads 42 are formed at a position deviating from immediately above the capacitance contact plugs 41. However, according to the DRAM 60 of the embodiment, since the bottom face of the capacitance contact pads 42 and the upper face of the capacitance contact plugs 41 are integrally formed, the capacitance contact pads 42 and the capacitance contact plugs 41 are connected at the overlapping part in the plan view.

According to the manufacturing method of the embodiment, as shown in FIG. 25B, a part of the upper face of the titanium laminated film 40A and the tungsten film 40B embedded in the capacitance contact opening portions 35 is removed at the patterning time, and the titanium alloy layer 40a and the tungsten layer 40b are formed.

That is, the capacitance contact plugs 41 of the embodiment are hybrid plugs including the layer formed of the polysilicon layer 38a, the cobalt silicide layer 39a, the titanium alloy layer 40a, and the tungsten layer 40b. The upper face of the cobalt silicide layer 39a which becomes the contacts is coated with the metal layer.

Accordingly, it is prevented that solution for the etching process dissolves the cobalt silicide layer 39a when the titanium laminated film 40A and the tungsten film 40B are patterned by that etching process. Therefore, it is possible to improve connection reliability.

In the manufacturing method of the embodiment, the metal layer formed of the titanium alloy layer 40a and the tungsten layer 40b constituting the capacitance contact plug 41 is formed integrally with a part of the capacitance contact pad 41 as described above. The capacitance contact plug 41 and the capacitance contact pad 42 are integrally formed, and the metal layer constituting the capacitance contact plug 41 and the capacitance contact pad 42 are integrally formed. Thus, it is possible to improve connection reliability while suppressing contact resistance.

According to the manufacturing method of the embodiment, it is preferable that the upper face of non-connection part of the metal layer (i.e., the upper face of the metal layer exposed from the capacitance contact opening portions 35) is recessed from the upper face of the insulating film formed of the SOD film 33 provided over the substrate. The non-connection part is other than the metal layer of the bottom face of the capacitance contact pads 42 and the upper face of the metal layer formed of the titanium alloy layer 40a and the tungsten layer 40b constituting the capacitance contact plugs 41. Accordingly, even when the capacitance contact pads 42 connected to be positioned with gaps in relation to the capacitance contact plugs 41 are densely laid out for miniaturization, it is possible to prevent a short-circuit between the capacitance contact pads 42 and the capacitance contact plugs 41 of the adjacent capacitor.

The amount of recession d from the upper face of the insulating layer formed of the SOD film 33 of the metal layer is not particularly limited, but is for example, about 100 nm.

In the peripheral circuit area, as shown in FIG. 25C, the wiring layer 130 for peripheral circuits including the contact plug connected to a diffusion region (not shown) provided over the substrate can be formed.

As described above, according to the manufacturing method of the embodiment, it is possible to simultaneously form the dot pattern such as the capacitance contact pads 42 and the line pattern such as the line layer 130 for peripheral circuits, which are difficult to simultaneously form in the related art, by one photolithography process. The dot pattern such as the capacitance contact pads 42 and the line pattern such as the line layer 130 for peripheral circuits, which are simultaneously formed, have the same line height.

As described above, the capacitance contact plugs 41 and the capacitance contact pads 42 are formed.

(Process of Forming Capacitor)

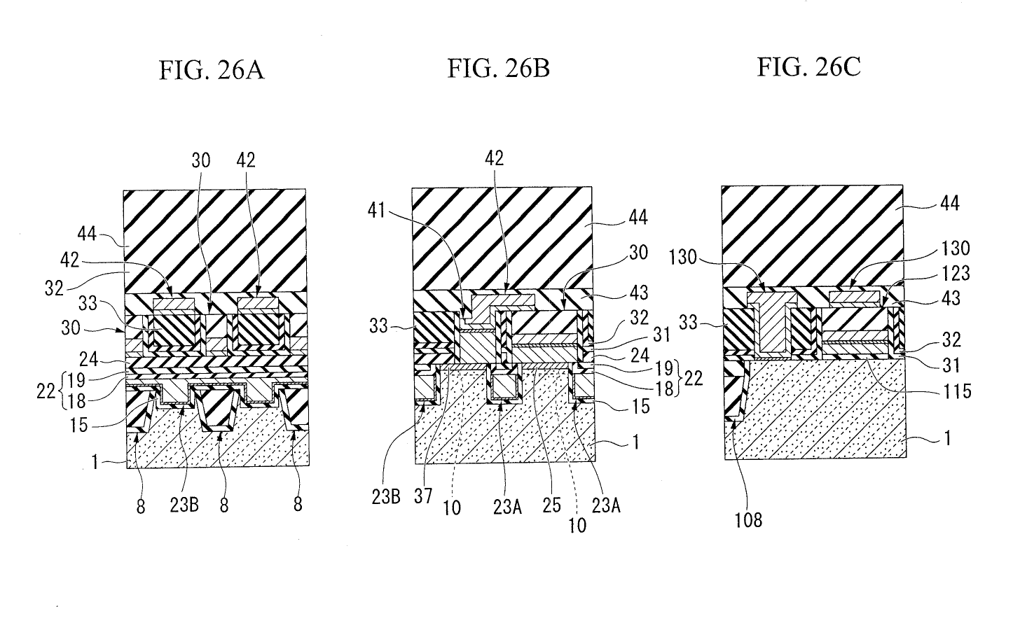

Then, the capacitor is formed as follows. First, as shown in FIG. 26A and FIG. 26C, a stopper film 43 is formed over the substrate over the memory cell area and the peripheral circuit area using, for example, a silicon nitride film. The capacitance contact pad 42 in the memory cell area and the wiring layer 130 in the peripheral circuit area are coated with the stopper film 43. Then, a third interlayer insulating film 44 is formed over the stopper film 43 using, for example, a silicon oxide film.

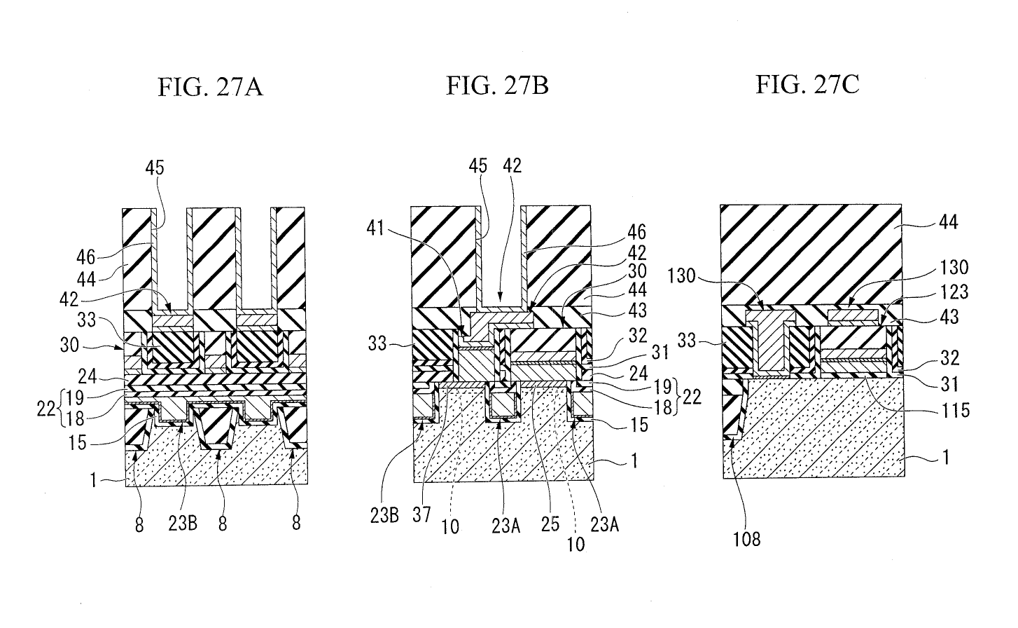

Then, as shown in FIG. 27A and FIG. 27B, a contact hole 45 is formed to expose a part of the upper faces of the capacitance contact pads 42. The contact hole 45 passing through the third interlayer insulating film 44 and the stopper film 43 formed over the capacitance contact pad 42 in the memory cell area. Then, lower electrode 46 of the capacitor element is formed using, for example, titanium nitride or the like, to cover the inner wall faces of the contact hole 45 and the upper face of the exposed capacitance contact pad 42. Accordingly, the bottom of the lower electrode 46 is connected to the upper face of the capacitance contact pad 42.

The following description is omitted with respect to the peripheral circuit area.

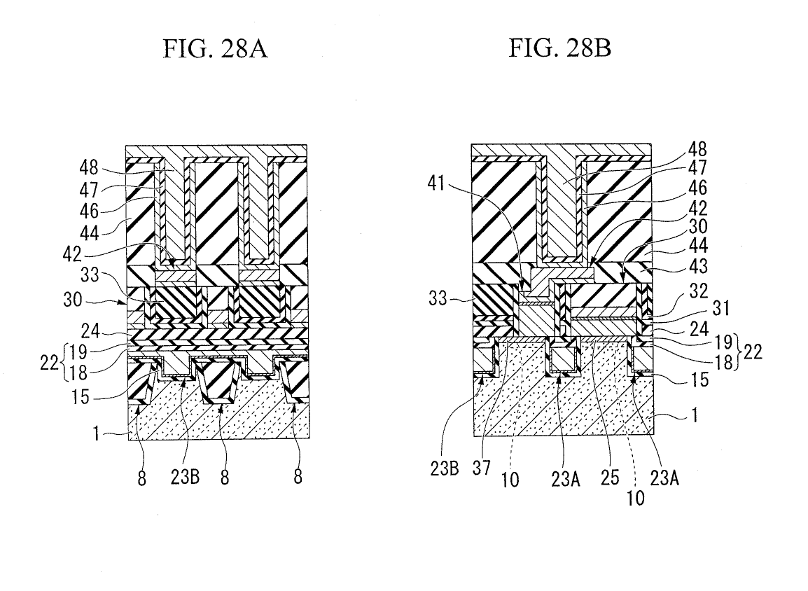

Then, as shown in FIG. 28A and FIG. 28B, a capacitance insulating film 47 is formed over the third interlayer insulating film 44 to cover the surfaces of the lower electrodes 46. As the capacitance insulating film 47, for example, zirconium oxide (ZrO₂), aluminum oxide (Al₂O₃), hafnium oxide (HfO₂), and a laminated film thereof may be used. Then, an upper electrode 48 of the capacitor elements is formed using, for example, titanium nitride or the like, to cover the surface of the capacitance insulating film 47. In such a manner, the capacitors are formed in the memory cell area.

(Process of Forming Wiring Layer)

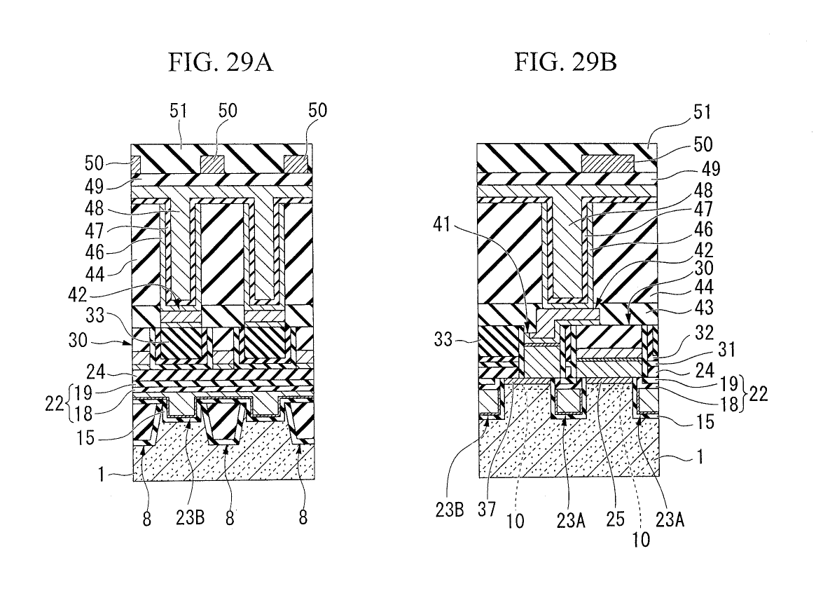

Then, a wiring layer is formed over the silicon substrate 1 with the capacitor element interposed therebetween. The wiring layer is formed as follows. First, as shown in FIG. 29A and FIG. 29B, a fourth interlayer insulating film 49 formed of, for example, a silicon oxide film or the like, is formed to cover the upper electrode 48. Then, upper metal lines 50 are formed of, for example, aluminum (Al), copper (Cu), or the like over the fourth interlayer insulating film 49. Thereafter, a protective film 51 is formed to cover the upper metal lines 50, and thus the manufacturing of memory cells of the DRAM is completed.

As described above, the DRAM 60 of the embodiment is manufactured.

As described above, the DRAM (semiconductor device) 60 of the embodiment, since the capacitance contact pad 42 is provided between the capacitance contact plug 41 and the lower electrode 46 of the capacitor in the memory cell area. Accordingly, the overlapping margin between the capacitance contact plug 41 and the capacitor is sufficiently secured and it is possible to improve connection reliability. The capacitance contact plug 41 has the laminated structure formed of the polysilicon layer 38a, the cobalt silicide layer 39a, the titanium alloy layer 40a, and the tungsten layer 40b from the semiconductor substrate 1 side. The upper face of a non-connection part of the metal layer is recessed from the upper face of the insulating layer 33. The non-connection part is other than the connection part of the bottom face of the capacitance contact pad 41 and the upper face of the metal layer is recessed from the upper face of the insulating layer 33. The upper face of the cobalt silicide layer 39a is coated with the metal layer. As described above, the position of the polysilicon layer 38a and the cobalt silicide layer 39a being in contact with the metal layer is recessed from the upper face of the insulating layer 33, and the upper face of the cobalt silicide layer 39a is coated with the metal layer. Accordingly, melting of the cobalt silicide layer 39a is prevented at the time of the wet process. Therefore, it is possible to provide the DRAM 60 with high connection reliability.

The method of manufacturing the DRAM (semiconductor device) 60 of the embodiment includes the following processes. The capacitance contact opening portion (contact hole) 35 is formed to pass through the insulating layer (SOD film) 33 of the memory cell area. The inside of the capacitance contact opening portions 35 is filled with polysilicon. The etch-back process is performed to recess the upper face thereof from the upper face of the insulating layer 33 to form the polysilicon layer 38a. The cobalt silicide layer (silicide layer) 39a is formed over the polysilicon layer 38a. The capacitance contact opening portion 35 is formed. The metal film including of the titanium laminated film 40A and the tungsten (W) film 40B is formed by sequentially laminating titanium nitride (TiN) and titanium (Ti) over the insulating layer 33 over the memory cell area and the peripheral circuit area. The metal film is patterned. Accordingly, while forming the metal layer coating the upper face of the cobalt silicide layer 39a, the capacitance contact plug 41 and the capacitance contact pad 42 are integrally formed in the memory cell area, and the wiring layer 130 are integrally formed in the peripheral circuit area. Accordingly, it is possible to simultaneously form the dot pattern such as the capacitance contact pad 42 and the line pattern such as the wiring layer 130, which are difficult to simultaneously form in the related art, by one photolithography process. Therefore, it is possible to reduce manufacturing costs.

In addition, since the metal layer coating the upper face of the cobalt silicide layer 39a is formed when patterning the metal film, a damage caused by etchant to the cobalt silicide layer 39a is prevented.

Moreover, since the upper face of a non-connection part of the metal layer is recessed from the upper face of the insulating layer 33, it is possible to suppress a short circuit with respect to the capacitance contact pad 42 formed over the insulating layer 33 of the adjacent memory cells. The non-connection part is other than the connection part of the bottom face of the capacitance contact pad 42 and the upper face of the metal layer constituting the upper portion of the capacitance contact plug 41.

Furthermore, according to the method of manufacturing the DRAM 60 of the embodiment, the bit contact plug and the bit line 30 are formed by one lithography and dry etching process, whereby misalignment of the bit contact plug and the bit line, such as the diameter of the bit contact plug being larger than the bit line width, does not occur. For this reason, it is possible to prevent the formation of a short circuit with another conductor.

The technical field of the invention is not limited to the embodiment, and may be variously modified within the scope which does not deviate from the concept of the invention. For example, in the DRAM of the embodiment, in the configuration of the memory cells, an example of using the recess channel transistors as the embedded gate transistors in which the word lines are completely embedded in the semiconductor substrate was shown, but the invention is not limited thereto, and various types of transistors may be applied.

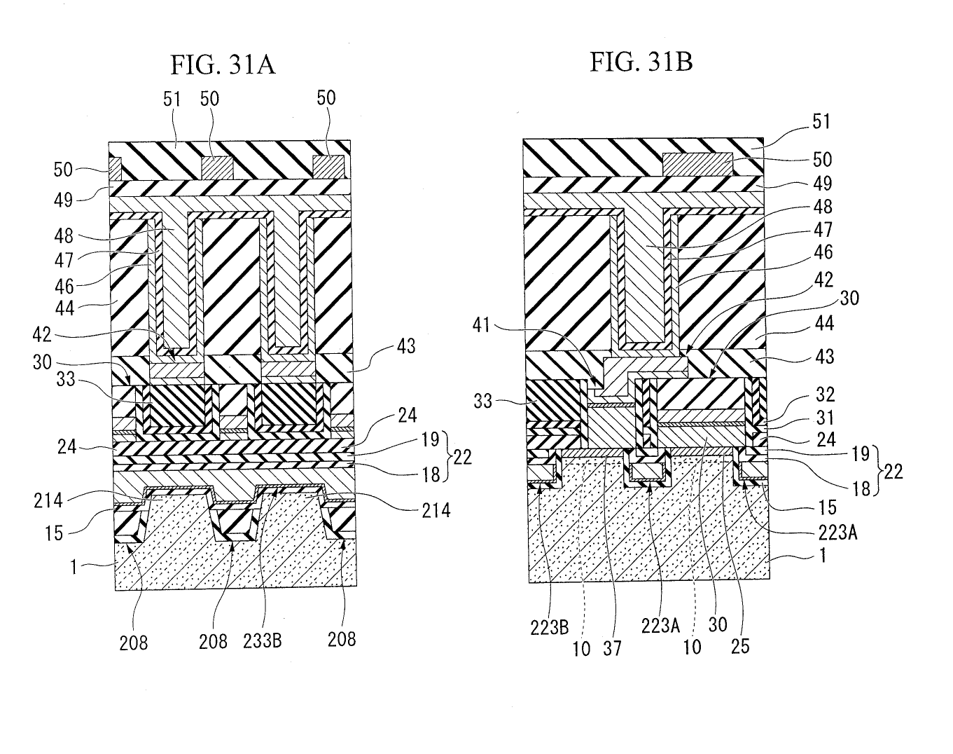

Specifically, a configuration of the memory cells may be exemplified as shown in FIG. 31A and FIG. 31B. In the same manner, the memory cells of the example are a laminated film structure which includes transistors with embedded gates being completely embedded in the semiconductor substrate, capacitors, and wiring layers. Configurations other than the configuration of the embedded gate transistor are the same as the embodiment. Accordingly, in the following description, the same reference numerals and signs are given to the same constituent elements as the semiconductor device of the embodiment, and the description thereof is not repeated.

As shown in FIG. 31A and FIG. 31B, in the embedded gate transistors of this example, a part of the bottom face of the embedded line 223B is embedded in the upper face of the STI element isolation films 208 provided in the lengthwise direction of the embedded line 223B as shown in FIG. 31A. That is, the upper face of the STI element isolation film 208 is lower than the surface of the silicon substrate 1 between the adjacent STI element isolation films 208. Accordingly, adjacent saddle-shaped silicon portions 214, with the part embedded in the STI element isolation film 208 and the gate insulating film 15 interposed therebetween, of the bottom of the embedded line 223B are provided on the upper face of the silicon substrate 1.

Herein, the embedded gate electrode 223A have the same structure as the embedded line 223B, and thus the same saddle-shaped silicon portion 214 is provided even in the embedded gate electrode 223A. The saddle-shaped silicon portion 214 can serve as channel when a potential difference between the source region and the drain region exceeds a threshold value. As described above, the embedded gate transistor of the example constitute saddle fin transistor having the same channel regions as the saddle-shaped silicon portion 214.

Subsequently, a method of manufacturing the saddle fin transistors having the above-described configuration will be described.

The process of forming the element isolation areas (see FIG. 3A to FIG. 6B) and formation of a hard mask in the process of forming the embedded gate electrodes (see FIG. 7) are the same as the embodiment.

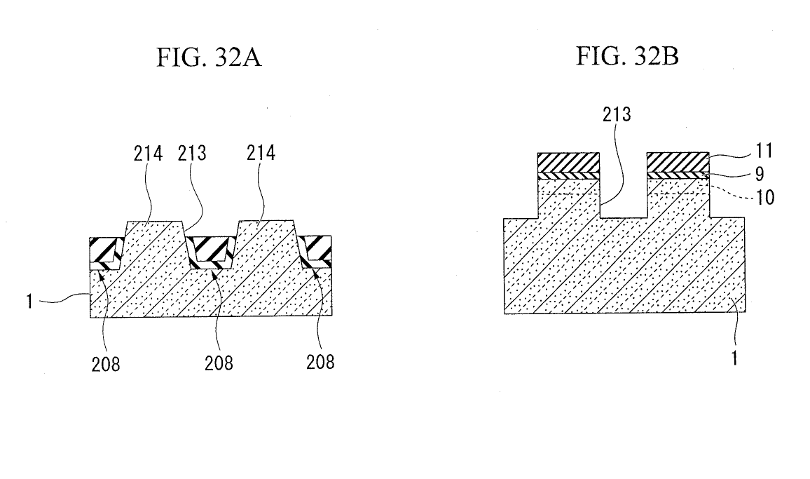

Then, as shown in FIG. 32A and FIG. 32B, the silicon substrate 1 exposed from the hard mask is etched by dry etching, thereby forming the gate electrode groove (trenches) 213. As shown in FIG. 32A, when the gate electrode groove 213 is formed, the STI element isolation films 208 is etched deeper than the silicon layer of the silicon substrate 1. Accordingly, the saddle-shaped silicon portion 214 remains at the part being into contact with the gate electrode grooves 213 at a part of the silicon layer higher than the upper face of the STI element isolation film 208. The saddle-shaped silicon portion 214 serves as the channel region of the transistor.

Then, as shown in FIG. 9A and FIG. 9B, the gate insulating film 15 is formed over the inner wall face of the gate electrode groove 213 and the whole surface of the substrate, and then gate electrode materials are sequentially laminated over the gate insulating film 15 to fill the inside of the gate electrode groove 213.

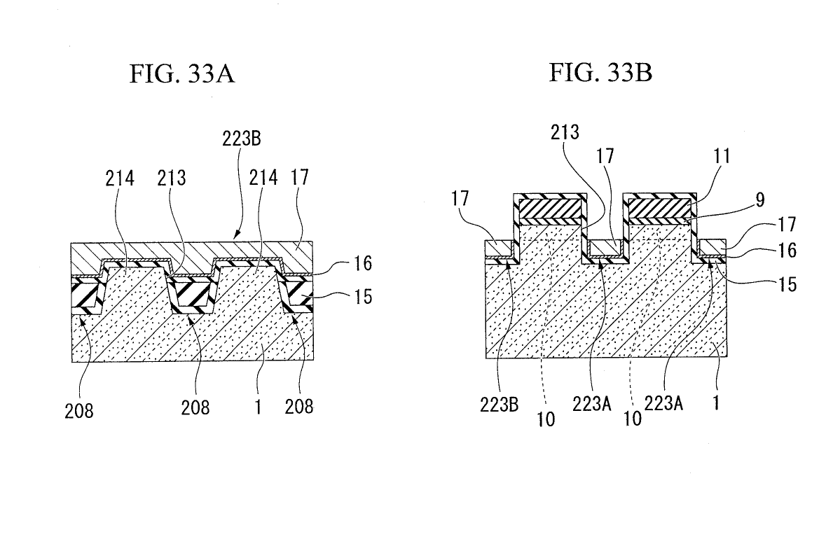

Then, as shown in FIG. 33A and FIG. 33B, the titanium nitride film 16 and the tungsten film 17 embedded in the gate electrode groove 213 are etched back such that the titanium nitride film 16 and the tungsten film 17 are allowed to remain only at the bottom of the gate electrodes groove 213. In such a manner, the embedded gate electrode (word line) 223A and the embedded line 223B embedded in the gate electrodes groove 213 provided in the silicon substrate 1 are formed.

The later processes are the same as the above-described embodiment.

As described in the example, there is an advantage of increasing on-current by applying the saddle fin transistor as the embedded gate transistor.

As used herein, the following directional terms “forward, rearward, above, downward, vertical, horizontal, below, and transverse” as well as any other similar directional terms refer to those directions of an apparatus equipped with the present invention. Accordingly, these terms, as utilized to describe the present invention should be interpreted relative to an apparatus equipped with the present invention.

Furthermore, the particular features, structures, or characteristics may be combined in any suitable manner in one or more embodiments.

The terms of degree such as “substantially,” “about,” and “approximately” as used herein mean a reasonable amount of deviation of the modified term such that the end result is not significantly changed. For example, these terms can be construed as including a deviation of at least ±5 percents of the modified term if this deviation would not negate the meaning of the word it modifies.

It is apparent that the present invention is not limited to the above embodiments, but may be modified and changed without departing from the scope and spirit of the invention.

What is claimed is:

1. A semiconductor device comprising:
an insulating film over a silicon substrate, the insulating film having an opening; and
a contact plug in the opening, the contact plug having a first top that is lower than an upper face of the insulating film.

2. The semiconductor device according to claim 1, further comprising:
a contact pad contacting the contact plug,
wherein the contact pad comprises the same material as the contact plug.

3. The semiconductor device according to claim 1, further comprising:
a contact pad having a bottom, the bottom being lower than the upper face of the insulating film.

4. The semiconductor device according to claim 1, wherein a contact pad contacts the contact plug.

5. The semiconductor device according to claim 1, further comprising:
a capacitor electrically connected to the contact pad.

6. The semiconductor device according to claim 4, further comprising:
a contact pad having a bottom, the bottom being lower than a second top of the opening,
wherein a first dimension in a first horizontal direction of the bottom of the contact pad is smaller than a second dimension in the first horizontal direction of the opening.

7. The semiconductor device according to claim 1, wherein the contact plug is in contact with the silicon substrate.

8. A semiconductor device comprising:
a contact plug comprising a first layer and a second layer, the first layer being over the second layer, the first layer performing as a first part of the contact plug and as a contact pad, and the second layer performing as a second part of the contact plug.

9. The semiconductor device according to claim 8, wherein the first layer comprises metal, and
wherein the second layer comprises semiconductor.

10. The semiconductor device according to claim 8, wherein the first layer comprises a first metal layer and a second metal layer.

11. The semiconductor device according to claim 10, wherein the first metal layer covers a first portion of the second metal layer.

12. The semiconductor device according to claim 10, further comprising:
an insulating film over the contact pad,
wherein a second portion of the second metal layer is in contact with the insulating film.

13. The semiconductor device according to claim 8,
wherein the contact plug is in contact with the silicon substrate.

14. The semiconductor device according to claim 8, further comprising:
a capacitor electrically connected to the contact pad.

15. The semiconductor device according to claim 8, further comprising:
an opening over the silicon substrate,
wherein the contact plug partially fills the opening.

16. The semiconductor device according to claim 15, further comprising:
wherein a width of a part of the contact pad in the opening is smaller than a width of the opening.

17. A semiconductor device comprising:
a contact plug over a silicon substrate;
a first insulating film over the silicon substrate; and
a contact pad,
wherein a first top of the contact plug is lower than a second top of the first insulating film, and
wherein a bottom face of the contact pad is lower than the second top of the first insulating film.

18. The semiconductor device according to claim 17, further comprising:
a capacitor electrically connected to the contact pad.

19. The semiconductor device according to claim 17, further comprising:
an opening over the silicon substrate,
wherein the contact plug partially fills the opening.

20. The semiconductor device according to claim 19, wherein a width of a part of the contact pad in the opening is smaller than a width of the opening.
